(19) United States
(12) Patent Application Publication
(10) Pub. No.: US 2005/0064337 A1
(43) Pub. Date: Mar. 24, 2005

(54) Image forming method and image exposure device

(75) Inventors: Atsushi Suganuma, Kanagawa (JP); Hiroshi Sunagawa, Kanagawa (JP); Norio Aoshima, Shizuoka-ken (JP); Toshifumi Inno, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/827,682

(22) Filed: Apr. 20, 2004

(30) Foreign Application Priority Data
Apr. 21, 2003 (JP) 2003-116161
Apr. 21, 2003 (JP) 2003-116162
Apr. 21, 2003 (JP) 2003-116163

(51) Int. Cl. G03F 7/00

(52) U.S. Cl. 430/300

(57) ABSTRACT

A method for forming an image on a planographic printing plate precursor including a substrate and an image recording layer disposed thereon, the layer including a hydrophobic precursor and a light-to-heat converting agent. The method includes an image exposing process of exposing the planographic printing plate precursor to infrared radiation to form an image on the image recording layer of the planographic printing plate precursor, and a post-heating process of heating the planographic printing plate precursor to a predetermined heating temperature.

### CROSS-REFERENCE TO RELATED APPLICATION

This application claims priority under 35USC 119 from Japanese Patent Application Nos. 2003-116161, 2003-116162 and 2003-116163, the disclosures of which are incorporated by reference herein.

### BACKGROUND OF THE INVENTION

1. Field of the Invention

The present invention relates to an image forming method and an image exposure device. Specifically, the invention relates to scanning exposure of an image by infrared radiation, an image forming method on a planographic printing plate by which plate-making can be carried out without any specific liquid developing process, and to an image exposure device used therefor.

2. Description of the Related Art

Recently, laser technology has been developed dramatically. Specifically, solid laser and semiconductor laser emitting infrared radiation having a wavelength of 760 nm to 1200 nm (hereinafter suitably referred to as “infrared laser”) and having high output and small size can be readily available. Specifically, in the art of planography, these infrared laser are very useful as a recording light source of a CTP (Computer to Plate) system, which makes a printing plate directly using a digital data from a computer and the like.

According to this situation, many planographic printing plates for the above CTP system have been investigated. Among these, a planographic printing plate precursor that requires no developing process, which can be attached to a printer without any developing process after exposure and used for printing has been investigated aiming at streamlining of processes and solving a problem of waste treatment, and various methods have been proposed.

One of the method for eliminating a developing process is called as developing-on-press, which includes exposing a planographic printing plate precursor, attaching the exposed precursor on a cylinder of a printer and supplying dampening water and ink thereto while revolving the cylinder to remove a non-image portion of the planographic printing plate precursor. Namely, it is a method in which a planographic printing plate precursor is directly attached to a printer after completion of exposure and is treated by conventional printing steps. According to this method, a liquid development process using a conventional developer can be eliminated, which makes streamlining of printing preparation processes and elimination of treatment of develop waste possible.

As such planographic printing plate precursor, for example, WO94/23954 suggests a planographic printing plate precursor including a substrate and a hydrophilic layer provided thereon, the layer has been crosslinked and includes a microcapsulated heat melting substance. In this printing plate, microcapsules are collapsed by the action of heat generated in a laser exposure area, whereby a lipophilic substance in the capsules elutes and makes the surface of the hydrophilic layer hydrophobic.

Furthermore, as another examples of a planographic printing plate precursor using microcapsules that can be collapsed by heat, a planographic printing plate precursor using microcapsules including a photopolymerizable monomer and a photosensitive resin, and a planographic printing plate precursor using microcapsules including a lipophilic component that interacts with the three dimensionally-crosslinked hydrophilic layer have been suggested. (For example, see Japanese Patent Application Laid-Open (JP-A) No. 62-250454 and Japanese Patent No. 3206297.) These planographic printing plate precursors require no developing process. However, these methods have a problem that, when a metal plate such as an aluminum plate is used as a substrate, the heat to be used for image-forming is diffused on the substrate, which leads to insufficient progress of curing of a recording layer on the interface between the substrate and the recording layer, insufficient strength of the image portion and deterioration of printing durability.

### SUMMARY OF THE INVENTION

An object of the present invention is to provide an image forming method that can form an image by scanning exposure based on a digital signal without a special liquid development process and can afford a planographic printing plate superior in printing durability, and an image exposure device used therefor, aiming at solving the above-mentioned conventional problems.

The present inventors have done intensive studies and found that the above-mentioned object can be accomplished by carrying out image exposure on a planographic printing plate precursor, which includes the recording layer described below, and heating the planographic printing plate to a predetermined temperature range, which resulted in the completion of the invention.

A first aspect of the invention is to provide a method for forming an image on a planographic printing plate precursor including a substrate and an image recording layer disposed thereon. The image recording layer includes a hydrophobic precursor and a light-to-heat converting agent. The method includes: exposing the planographic printing plate precursor to infrared radiation to form an image on the image recording layer of the planographic printing plate precursor; and post-heating the planographic printing plate precursor to a predetermined heating temperature.

The hydrophobic precursor applicable to the image recording layer of the image forming method of the first aspect of the invention includes (a) microcapsules including a compound having a heat reactive group, (b) thermoplastic polymer particles or (c) polymer particles including a heat reactive group.

In the first aspect of the invention, it is possible to employ an image recording layer including a polymerizable compound, a polymerization initiator and a light-to-heat converting agent instead of an image recording layer including a hydrophobic precursor and a light-to-heat converting agent.

The polymerizable compound used in the image recording layer including a polymerizable compound, a polymerization initiator and a light-to-heat converting agent may be contained in microcapsules. As an alternative, the polymerizable compound may be (e) polymer particles including a polymerizable group. Hereinafter, the polymerizable compound contained in microcapsules may be sometimes referred to as “(d) microcapsules containing a polymerizable compound”.

The heating temperature in the post-heating process is preferably in the range of 35° C. to 230° C., and more preferably in the range of 35° C. to 200° C.

The image exposure device used for the above-mentioned image forming method of the first aspect includes: a retention member to which the planographic printing plate precursor can be attached, the member retaining the attached planographic printing plate precursor, means for exposing the planographic printing plate precursor retained by the retention member to infrared radiation to form an image on the image recording layer of the planographic printing plate precursor, and means for post-heating the planographic printing plate precursor which has been detached from the retention member after the image formation to the heating temperature by thermal energy or electromagnetic energy supplied from the heat supplying portion extending linearly or planerly.

A second aspect of the present invention is to provide a method for forming an image on a planographic printing plate precursor including a substrate and an image recording layer disposed thereon. The image recording layer includes a hydrophobic precursor and a light-to-heat converting agent. The method includes: applying scanning exposure to the planographic printing plate precursor with infrared radiation to form an image on the image recording layer of the planographic printing plate precursor; and locally post-heating a heating area including an arbitrary area exposed to the infrared radiation on the image recording layer of the planographic printing plate precursor during the exposure of the planographic printing plate precursor, to a predetermined heating temperature, after the irradiation of the exposure area in the heating area with infrared radiation.

The hydrophobic precursor applicable to the image recording layer according to the method of the second aspect of the invention includes (a) microcapsules including a compound having a heat reactive group, (b) thermoplastic polymer particles or (c) polymer particles including a heat reactive group.

In the second aspect of the invention, it is possible to employ an image recording layer including a polymerizable compound, a polymerization initiator and a light-to-heat converting agent instead of an image recording layer including a hydrophobic precursor and a light-to-heat converting agent.

The polymerizable compound used in the image recording layer including a polymerizable compound, a polymerization initiator and a light-to-heat converting agent may be contained in microcapsules. As an alternative, the polymerizable compound may be (e) polymer particles including a polymerizable group. Hereinafter, the polymerizable compound contained in microcapsules may be sometimes referred to as “(d) microcapsules containing a polymerizable compound”.

The heating temperature in the post-heating process is preferably in the range of 35° C. to 230° C., and more preferably in the range of 35° C. to 200° C. Furthermore, the heating of the heating area to the heating temperature is preferably carried out within 1 min, and more preferably within 30 sec after the completion of the exposure of the exposure area in the heating area.

The image exposure device used for the above-mentioned image forming method of the second aspect includes: a retention member to which the planographic printing plate precursor can be attached, the member retaining the attached planographic printing plate precursor, exposing means for scanning exposing the planographic printing plate precursor retained by the retention member with infrared radiation to form an image on the image recording layer of the planographic printing plate precursor, and means for locally post-heating the heating area including the arbitrary exposure area on the planographic printing plate precursor to which the infrared radiation has been irradiated by the exposing means during the exposure of the planographic printing plate precursor to infrared radiation, to the predetermined heating temperature, after the irradiation to the exposure area in the heating area with infrared radiation.

A third aspect of the present invention is to provide a method for forming an image on a planographic printing plate precursor including a substrate and an image recording layer disposed thereon. The image recording layer includes a hydrophobic precursor and a light-to-heat converting agent. The method includes: applying scanning exposure to the planographic printing plate precursor with infrared radiation to form an image on the image recording layer of the planographic printing plate precursor; and locally heating a heating area including an arbitrary exposure area to which the infrared radiation is irradiated in the image recording layer of the planographic printing plate precursor during the exposure of the planographic printing plate precursor, to a predetermined heating temperature, during the exposure of the exposure area in the heating area.

The hydrophobic precursor applicable to the image recording layer according to the method of the third aspect of the invention includes (a) microcapsules including a compound having a heat reactive group, (b) thermoplastic polymer particles or (c) polymer particles including a heat reactive group.

In the third aspect of the invention, it is possible to employ an image recording layer including a polymerizable compound, a polymerization initiator and a light-to-heat converting agent instead of an image recording layer including a hydrophobic precursor and a light-to-heat converting agent.

The polymerizable compound used in the image recording layer including a polymerizable compound, a polymerization initiator and a light-to-heat converting agent may be contained in microcapsules. As an alternative, the polymerizable compound may be (e) polymer particles including a polymerizable group. Hereinafter, the polymerizable compound contained in microcapsules may be sometimes referred to as “(d) microcapsules containing a polymerizable compound”.

The heating temperature in the heating process is preferably in the range of 35° C. to 230° C., and more preferably in the range of 35° C. to 200° C.

The image exposure device used for the above-mentioned image forming method of the third aspect includes: a retention member to which the planographic printing plate precursor can be attached, the member retaining the attached planographic printing plate precursor; exposing means for scanning exposing the planographic printing plate precursor retained by the retention member with infrared radiation to form an image on the image recording layer of the planographic printing plate precursor; and means for locally heating the heating area including the arbitrary exposure area to which the infrared radiation is irradiated on the image recording layer of the planographic printing plate precursor during the exposure of the planographic printing plate precursor, to the predetermined heating temperature, during the irradiation of the exposure area in the heating area.

The image-forming mechanism of the planographic printing plate precursor according to an embodiment which employs an image recording layer including a hydrophobic precursor and a light-to-heat converting agent in the first to third aspects of the invention will be explained hereinafter. In an embodiment in which an image recording layer includes a hydrophobic precursor and a light-to-heat converting agent in the first to third aspects of the invention, the image recording layer is characterized by including a hydrophobic precursor and a light-to-heat converting agent. The hydrophobic precursor forms a hydrophobic portion (an image portion) with energy of infrared radiation of image exposure and/or energy generated by exposure from the light-heat converting agent (hereinafter, these may be sometimes simply referred to as “energy of image exposure”). On the other hand, an unexposed portion is hydrophilic, and thus developing-on-press becomes possible with dampening water during printing and ink supply.

Examples of the image recording layer including a hydrophobic precursor and a light-to-heat converting agent which is preferably applicable to a planographic printing plate precursor of the first to third aspects of the invention include the following first to third embodiments of a recording layer.

In the image recording layer including (a) microcapsules containing a compound having a heat reactive group (hereinafter, sometimes referred to as a “heat reactive compound”) and a light-to-heat converting agent, which is the first embodiment of the image recording layer, the microcapsule wall collapses or becomes permeable by infrared radiation energy during image exposure and thermal energy generated from a light-to-heat converting agent by the exposure, and the compound having a heat reactive group contained in the microcapsules is released (exudated) from the microcapsules. Subsequently, a polymerizing reaction or an addition reaction of the reactive compound take place, whereby a surface hydrophobic portion, i.e. an image portion, is formed. Especially, in case where the heat reactive group of the heat reactive compound is a polymerizable group, it is preferable for the image recording layer to contain a polymerization initiator. A reaction initiator (active species) is generated from the polymerization initiator due to energy of image exposure, and initiates and proceeds the polymerization reaction of the heat polymerizable compound released (exudated) from microcapsules.

Furthermore, the embodiment including (b) thermoplastic polymer particles or (c) polymer particles including a heat reactive group, and a light-to-heat converting agent, which is the second or third embodiment of the image recording layer, has the following mechanism: polymer particles are fused each other or coagulated each other by crosslinking reaction such as polymerization reaction, addition reaction, or the like by infrared radiation energy during image exposure and thermal energy from the light-to-heat converting agent by exposure, whereby a surface hydrophobic portion, i.e., an image portion is formed. Especially, in the third embodiment, when the heat reactive group included in the polymer particules is a polymerizable group, it is preferable for the image recording layer to contain a polymerization initiator. This polymerization initiator serves to initiate and proceed the crosslinking (polymerizing) reaction of polymer particles.

The image-forming mechanism of the planographic printing plate precursor according to an embodiment which employs an image recording layer including a polymerizable compound, a polymerization initiator and a light-to-heat converting agent in the first to third aspects of the invention will be explained hereinafter. In an embodiment in which an image recording layer includes a polymerizable compound, a polymerization initiator and a light-to-heat converting agent in the first to third aspects of the invention, the image recording layer is characterized by including a polymerizable compound, a polymerization initiator and a light-to-heat converting agent. The polymerizable compound forms a hydrophobic image portion by causing a polymerization reaction and being cured with energy of image exposure. On the other hand, in an unexposed portion, uncured components are easily removed due to dampening water during printing, function of ink and stress during printing.

Examples of the image recording layer including a polymerizable compound, a polymerization initiator and a light-to-heat converting agent which is preferably applicable to a planographic printing plate precursor of the first to third aspects of the invention include the following fourth and fifth embodiments of a recording layer.

In the image recording layer including (d) microcapsules containing a polymerizable compound, a polymerization initiator and a light-to-heat converting agent, which is the fourth embodiment of the image recording layer, the microcapsule wall collapses or becomes permeable by energy of image exposure, and the polymerizable compound contained in the microcapsules is released (exudated) from the microcapsules. A reaction initiator (active species) is generated from the polymerization initiator due to energy of image exposure, and initiates and proceeds the polymerization reaction of the polymerizable compound released (exudated) from microcapsules, whereby an image portion is formed.

In the image recording layer including (e) polymer particles including a polymerizable group, a polymerization initiator and a light-to-heat converting agent, which is the fifth embodiment of the image recording layer, a reaction initiator (active species) generated from the polymerization initiator due to energy of image exposure initiates and proceeds the crosslinking (polymerizing) reaction of the polymer particles, whereby an image portion is formed.

However, in these planographic printing plate precursors, diffusion of heat to the substrate occurs in the vicinity of the interface between the recording layer and the substrate, as mentioned above, which leads to insufficient curing reaction due to unreacted compound such as a polymerizable compound having a heat reactive group (hereinafter, sometimes referred to as “heat reactive compound”) or residual polymerization initiator, or due to an area in which the particles are not sufficiently fused or crosslinked. Therefore, an image being strong and having superior printing durability has not been obtained yet.

In the method of the first aspect of the invention, it is considered that the whole energy for the image-forming can be increased by heating the planographic printing plate precursor by energy such that the microcapsule wall material in the non-image portion does not become permeable or by energy such that the polymer particles in the non-image portion do not fuse or crosslink, after the image exposure of the planographic printing plate precursor (hereinafter suitably referred to as “post-heating”), which allows formation of an image having rigidity and superior printing durability. Specifically, in the recording layer using the microcapsules, unreacted polymerization initiator is decomposed by heating to form a new active species, which acts on unreacted heat reactive compound or a polymerizable compound to initiate and proceed the polymerization reaction thereof, increase the movabilities of the active species and the heat reactive compound or a polymerizable compound, and to accelerate the proceeding of the polymerization reaction. In the case of the particles polymer, it is considered that the fusion of the insufficient fused surfaces of the adjacent particles is accelerated by post-heating, and that the crosslinking reaction is also accelerated due to the same reason as the polymerization reaction to form a strong hydrophobic portion. In view of these, it is expected that the method of the invention exhibits a remarkable effect when microcapsules which generate a synergetic effect between increase of the active species and increase of movability, are used.

In the image exposure device according to the method of the first aspect of the invention, a hydrophobic portion that is selectively strong only on the desired image portion area can be formed by supplementally supplying energy useful for forming of the hydrophobic portion in the exposure portion of the recording layer by heating of the planographic printing plate precursor which has been detached from the retention member after image-forming by the retention member, by means of post-heating, to a predetermined heating temperature, by thermal energy or electromagnetic energy supplied from the heat supplying portion extended linear or planer.

In the method of the second aspect of the invention, it is considered that the thermal energy for the image-forming is increased by locally heating the area including the image-exposed area of the planographic printing plate precursor by energy such that the microcapsule wall material in the non-image portion does not become permeable or by energy such that the polymer particles in the non-image portion do not fuse or crosslink, after the image exposure of the planographic printing plate precursor (hereinafter suitably referred to as “post-heating”), which allows formation of an image being strong and having superior printing durability. Specifically, in the recording layer using the microcapsules, unreacted polymerization initiator is decomposed by heating to form new active species, which acts on unreacted heat reactive compound or a polymerizable compound to initiate and proceed the polymerization reaction thereof, increases the movabilities of the active species and the heat reactive compound or a polymerizable compound, and accelerates the proceeding of the polymerization reaction. In the case of the polymer particles, it is considered that the fusion of the insufficient fused surfaces of the adjacent particles is accelerated by post-heating, and that the crosslinking reaction is also accelerated due to the same reason as the polymerization reaction to form a strong hydrophobic portion. In view of these, it is expected that the method of the invention exhibits a remarkable effect when microcapsules which generate a synergetic effect between increase of the active species and increase of movability, are used.

The image exposure device according to the method of the second aspect of the invention, the heating area including an arbitrary exposure area of the planographic printing plate precursor on which planographic printing plate precursor is irradiated with the infrared beam by the means for exposing is locally heated by the means for post-heating to the above-mentioned heating temperature before or after irradiation to the exposure area in the heating area with infrared radiation. Accordingly, in the case even the polymerization reaction is difficult to proceed sufficiently due to insufficient generation of active species by decomposition of the initiator in the vicinity of the interface between the recording layer and the substrate by merely the thermal energy by infrared radiation and low movability of the polymerizable compound, the generation of new active species and movability of the compound involved in the reaction are improved according to the increase of temperature of the recording layer itself, whereby the polymerization reaction in the vicinity of the interface between the recording layer and the substrate can be accelerated. Similarly, the fusion between the particles becomes more sufficient and strong by reheating.

In the method of the third aspect of the invention, it is considered that the whole thermal energy for the image-forming is increased by locally heating the area (heating area) including the area (exposure area), on which infrared radiation is irradiated to expose, on the planographic printing plate precursor, during the irradiation of infrared radiation to the exposure area, by energy such that the microcapsule wall material in the non-image portion does not become permeable or by energy such that the polymer particles in the non-image portion do not fuse or crosslink, during the image exposure of the planographic printing plate precursor, whereby an image having superior printing durability can be formed. Specifically, in the recording layer using microcapsules, decomposition reaction of the polymerization initiator is accelerated by heating, and much polymerization initiator is activated as compared with the case when only infrared radiation exposure is used, to generate sufficient amount of active species, which acts on the heat reactive compound or a polymerizable compound to initiate and proceed the polymerization reaction thereof, improve movabilities of the active species and the heat reactive compound or a polymerizable compound by heat, and to accelerate proceeding of the polymerization reaction. Furthermore, when a microparticle polymer is used, the calorie supplied is increased, whereby softening and melting of particles are carried out quickly and fusion of the surfaces of the adjacent particles is accelerated. Furthermore, when a crosslinking-type or a polymerization-type particles having heat reactive functional group are used, crosslinking (polymerization) reaction is accelerated due to the same reason as mentioned for the polymerization reaction, since the particles have heat reactive functional group. Therefore, it is considered that a strong image portion is formed in either embodiment.

### BRIEF DESCRIPTION OF THE DRAWINGS

FIG. 1 is a side-view showing the structure of the image exposure device according to a first embodiment of the image forming method of the first aspect of the present invention.

FIG. 2 is a perspective view showing the structures of an exposure head and a feeding mechanism therefor in the image exposure device as shown in FIG. 1.

FIG. 3 is a perspective view showing the structure of the post-heating apparatus in the image exposure device as shown in FIG. 1.

FIG. 4 is a side-view of the post-heating apparatus as shown in FIG. 3.

FIG. 5 is a perspective view showing the structure of a coil unit in the post-heating apparatus as shown in FIG. 3.

FIG. 6 is a side-view showing the structure of the image exposure device according to a second embodiment of the image forming method of the first aspect of the invention.

FIG. 7 is a side-view showing the structure of the image exposure device according to the image forming method of the second aspect of the invention.

FIG. 8 is a perspective view showing the structures of an exposure head and a feeding mechanism therefor in the image exposure device as shown in FIG. 7.

FIG. 9 is a side-view showing the structure of the image exposure device according to the image forming method of a third aspect of the invention.

FIG. 10 is a perspective view showing the structures of the exposure head and a feeding mechanism therefor in the image exposure device as shown in FIG. 9.

### DETAILED DESCRIPTION OF THE INVENTION

[Structure of an Image Exposure Device According to an Image Forming Method of a First Aspect]

Firstly, an image exposure device on which an image forming method according a first aspect of the present invention is explained with referring to the drawings.

### IMAGE EXPOSURE DEVICE ACCORDING TO A FIRST EMBODIMENT

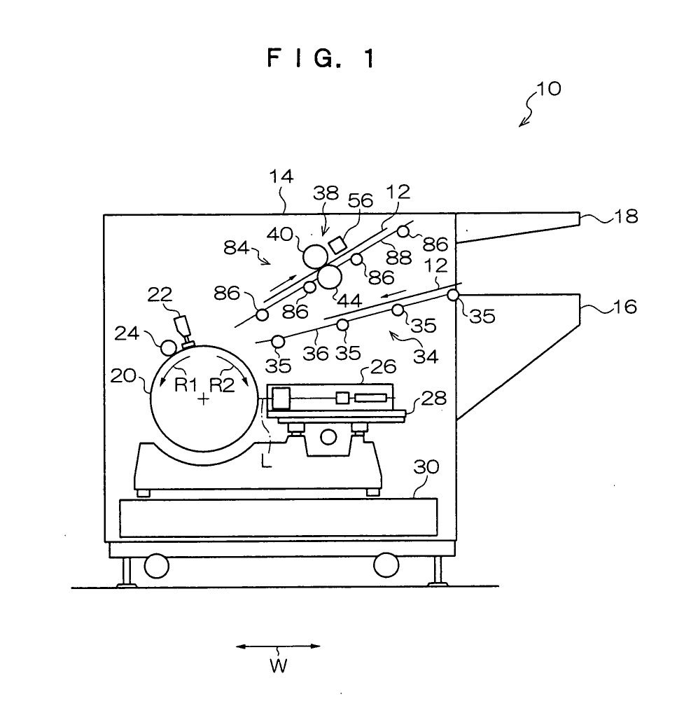

FIGS. 1 to 5 show the image exposure device of the first embodiment according to the invention. In the image exposure device 10, a planographic printing plate precursor 12 is scanning-exposed by infrared laser L (hereinafter referred to as “IR laser L”) modulated by digital image information, whereby an image (latent image) corresponding to the digital image information is formed on the planographic printing plate precursor 12. The planographic printing plate precursor 12 is called as a treatless printing plate since it requires no specific developing process. The planographic printing plate precursor includes a substrate made of aluminum or an aluminum alloy and an image recording layer formed on the substrate. The image recording layer (hereinafter, sometimes simply referred to as “recording layer”) may include a hydrophobic precursor and a light-to-heat converting agent; or it may include a polymerizable compound, a polymerization initiator and a light-to-heat converting agent. These planographic printing plate precursors will be detailed later.

As shown in FIG. 1, in the image exposure device 10 is provided a body casing 14 as an outer shell portion of the apparatus. To the body casing 14 is attached a plate feeding stage 16 for mounting a bundle of the planographic printing plate precursors 12 on one of the side plate portions along the width direction of the apparatus (direction of arrow W), and on the upper side of the plate feeding stage 16 is provided an ejection tray (receiving portion) 18 for ejecting the exposed planographic printing plate precursor 12. In the body casing 14 is rotatably provided a columnar outer drum (retention member) 20 to which one planographic printing plate precursor 12 can be detached. On the peripheral portion of the outer drum 20 are provided a chuck mechanism (retention member) 22 for chucking a tip portion and a back end portion of the planographic printing plate precursor 12 on the outer drum 20, and a guide roller 24 for winding the planographic printing plate precursor 12 on the peripheral surface of the outer drum 20.

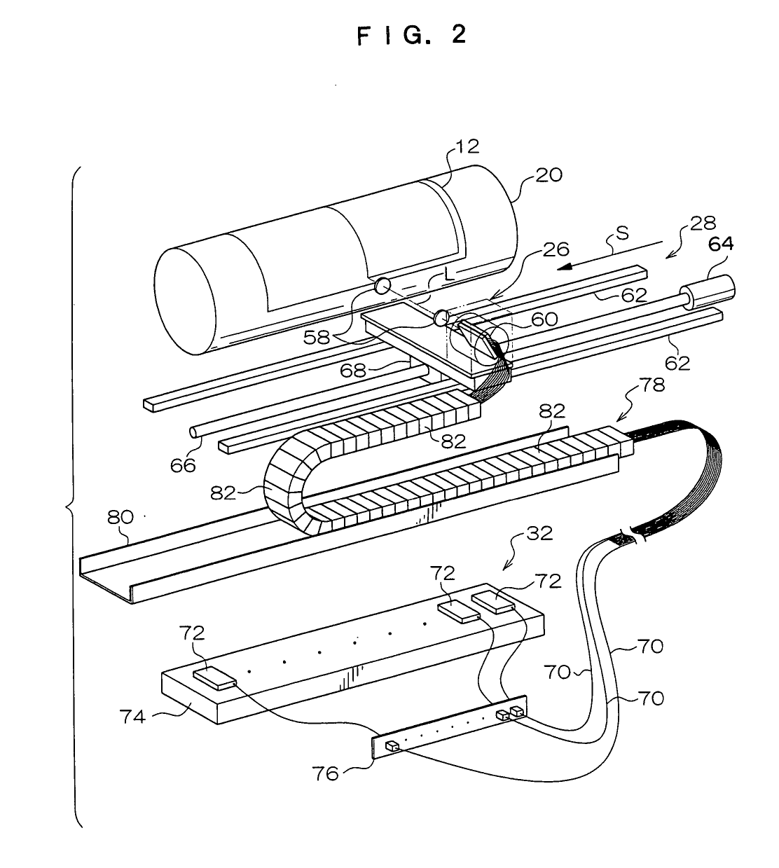

In the body casing 14 are provided an exposure head (means for exposing) 26 opposing to the outer drum 20 and a feeding mechanism (means for exposing) 28 for movably supporting the exposure head 26 along the sub-scanning direction. The exposure head 26 and the feeding mechanism 28 scanning-exposure the planographic printing plate precursor 12 attached on the outer drum 20 by the IR laser L modulated based on the digital image information to form an image corresponding to the digital image information on the planographic printing plate precursor 12. Furthermore, in the body casing 14, a light source box 30 is provided on the lower side of the outer drum 20, and the light source box 30 accommodates an LD light source portion (means for exposing) 32 (see FIG. 2) for supplying IR laser L to the exposure head 26.

As shown in FIG. 1, in the body casing 14 of the image exposure device 10 is provided a feeding mechanism 34 for conveying the planographic printing plate precursor 12 mounted on the plate feeding stage 16 to the outer drum 20. The feeding mechanism 34 includes plural conveyer rollers 35 provided along the feeding pathway of the planographic printing plate precursor 12 and a plate-shaped guide member 36. Furthermore, on the end of the plate feeding stage 16 of the feeding mechanism 34 is provided a separation mechanism (omitted in the drawing) for separating one planographic printing plate precursor 12 from the bundle of the planographic printing plate precursors 12 stacked on the plate feeding stage 16 and for supplying the one planographic printing plate precursor 12 to the feeding pathway.

In the image exposure device 10, when the planographic printing plate precursor 12 is conveyed by the feeding mechanism 34 in the vicinity of the upper end portion of the outer drum 20, the tip portion of the planographic printing plate precursor 12 is chucked on the outer drum 20 by the chuck mechanism 22, and the outer drum 20 begins to rotate in a predetermined normal direction (direction of arrow R1 in FIG. 1). The planographic printing plate precursor 12 whose tip portion has been fixed on the outer drum 20 is wound on the peripheral surface of the outer drum 20 while the precursor 12 is pressurized to the surface of the outer drum 20 by the guide roller 24.

In the image exposure device 10, when the planographic printing plate precursor 12 has been wound on the outer drum 20 to the back end portion, the back end portion of the planographic printing plate precursor 12 is chucked on the outer drum 20 by the chuck mechanism 22. Accordingly, the planographic printing plate precursor 12 is entirely adhered on the peripheral surface of the outer drum 20, whereby the adhesion of the planographic printing plate precursor 12 on the outer drum 20 is completed. In the image exposure device 10, sub-scanning exposure of the planographic printing plate precursor 12 is carried out by moving the exposure head 26 in the sub-scanning direction by the feeding mechanism 28 in the state that the planographic printing plate precursor 12 has been adhered to the outer drum 20, and irradiating the planographic printing plate precursor 12 with the IR laser L irradiated from the exposure head 26. In the image exposure device 10, main scanning of the planographic printing plate precursor 12 can be carried out by revolving the outer drum 20 in the normal direction by revolution corresponding to the main scanning pitch in sync with the completion of one sub-scanning.

As shown in FIG. 2, on the exposure head 26 are provided a lens unit 58 composed of plural lenses, which constitutes an image-forming optical system, and a fiber holder 60 including a pair of supporting plate holding tip portions of the plural optical fibers 70 and a transparent protection plate for protecting the tip surfaces of the optical fibers 70 and the like. The exposure head 26 is mounted on a carrier 68, and moves along the sub-scanning direction (direction of arrow S of FIG. 2) with the carrier 68. The IR laser L each irradiated from the plural optical fibers 70 incidents in the lens unit 58, whereby the lens unit 58 forms an image on the planographic printing plate precursor 12 attached to the outer drum 20 to form a beam spot having a predetermined shape and size. Accordingly, plural beam spots aligned on a straight line inclined at a predetermined angle from the sub-scanning direction are formed on the planographic printing plate precursor 12, and the recording layer of the planographic printing plate precursor 12 is scanning-exposured by these beam spots.

The feeding mechanism 28 includes a pair of guide rail 62, which supports the carrier 68 slidably along the sub-scanning direction and a screw axis 66 connected to a motor unit 64. On the lower surface portion of the carrier 68 is fixed a female screw member 69 having a screw hole in the sub-scanning direction, and the screw axis 66 is screwed in the female screw hole of the female screw member 69. Accordingly, when the screw axis 66 is rotated by the motor unit 64, the exposure head 26 moves, with the carrier 68 along the sub-scanning direction by a distance corresponding to the revolution of the screw axis 66 in the direction (forward direction or reverse direction) corresponding to the revolution direction of the screw axis 66. In the image exposure device 10 of this embodiment, although the sub-scanning to the planographic printing plate precursor 12 is carried out only during the advancement of the exposure head 26, i.e., movement in the sub-scanning direction (direction of arrow S), the sub-scanning (reciprocate scanning) can be also carried out during advancement and retraction respectively.

As shown in FIG. 2, the other ends of the plural optical fibers 70 are connected to plural semiconductor lasers 72 in the LD light source portion 32 respectively. These semiconductor lasers 72 are fixed on a plate-shaped heat sink 74. In the halfway of the optical fibers 70 is provided a connector array 76, and the optical fibers 70 are capable of connecting and disconnecting the portion on the fiber holder 60 and the portion on the semiconductor laser 72 via the connector array 76. Accordingly, for example, when any of semiconductor laser LDs breaks down, the broken semiconductor laser 72 can be readily changed without disassembling the fiber holder 60 and the like.

The feeding mechanism 28 are provided with a tubular cable bear 78 and a canaliculate bear guide 80 each extending in the sub-scanning direction under the guide rail 62. The cable bear 78 has a structure in which a number of link fragment 82 divided along the longitudinal direction are linked serially, the fragments can be curved along the vertical direction. In the cable bear 78 were inserted the exposure head 26 side portions of the optical fibers 70 (tip portions). The bear guide 80 support the cable bear 78 from below and limits the movement of the cable bear 78 in forward or backward direction. Accordingly, during the movement of the exposure head 26 in the sub-scanning direction, the tip side of the optical fibers 70 moving with the exposure head 26 is protected by the cable bear 78, whereby the damage on the optical fibers 70 is prevented.

As shown in FIG. 1, in the body casing 14 of the image exposure device 10 is provided a conveyer mechanism 84 for conveying the planographic printing plate precursor 12 detached from the outer drum 20 to the ejection tray 18. The conveyer mechanism 84 includes plural conveyer rollers 86 provided along the conveyer pathway of the planographic printing plate precursor 12 and a plate-shaped guide member 88.

In the image exposure device 10, after the exposure (image-forming) on the planographic printing plate precursor 12 attached on the outer drum 20 is completed, the outer drum 20 is revolved in the reverse direction (direction of arrow R 2 in FIG. 1) while the back end portion and the tip portion of the planographic printing plate precursor 12 are released sequentially from the outer drum 20 by the chuck mechanism 22. In conjunction with this, the conveyer mechanism 84 begins to convey the planographic printing plate precursor 12 that has been delivered from the outer drum 20 to the inlet portion of the conveyer pathway to the ejection tray 18 by revolving the conveyer roller 86, and the planographic printing plate precursor 12 is ejected on the ejection tray 18.

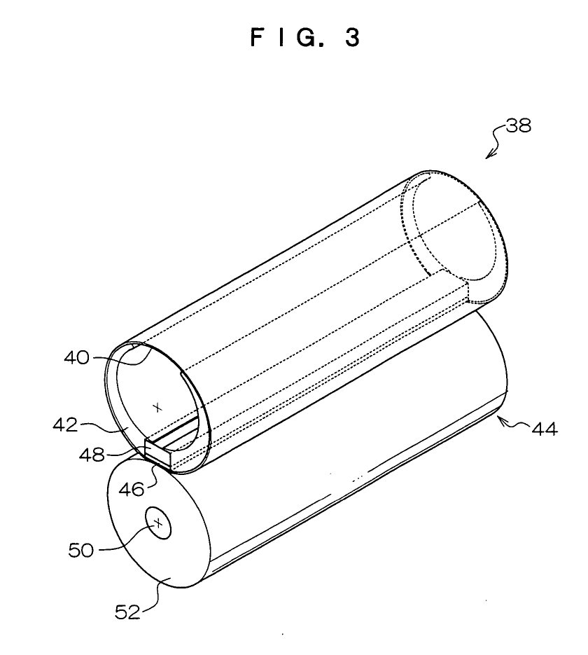

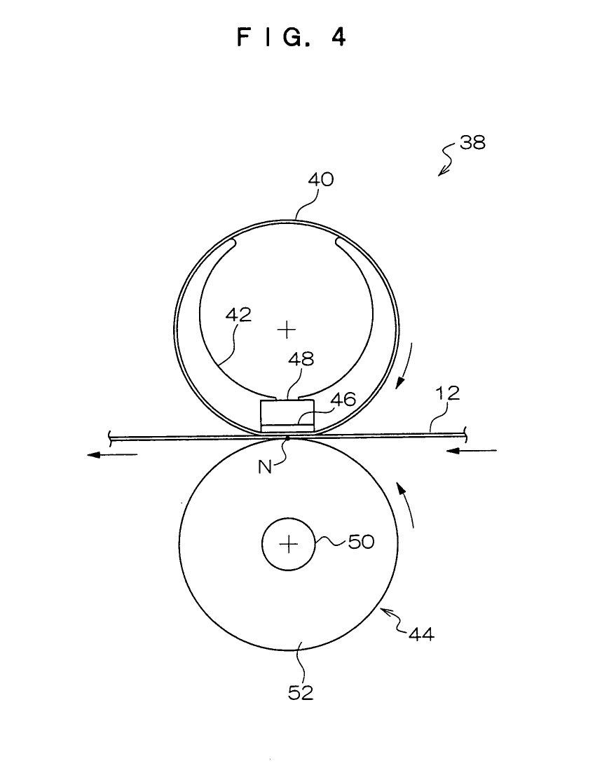

In the image exposure device 10, a post-heating apparatus (means for post-heating) 38 for heating (post-heating) whole planographic printing plate precursor 12 during conveying is provided on a conveyer mechanism (means for conveying) 84. The post-heating apparatus 38 heats the planographic printing plate precursor 12 by magnetic induction heating, and as shown in FIGS. 3 and 4, includes a heat resistant film 40 having no ends, a film guide 42 provided on the inner peripheral side of the heat resistant film 40 and a pressurizing roller 44 beared on the lower side of the heat resistant film 40. The film guide 42 has approximately C-shape in which the cross-section form opens upwards, and the length along the axial direction is longer than the width of the planographic printing plate precursor 12. In the lower end portion of the film guide 42 are buried a plate-shaped heating member 46 made of a magnetic metal and a coil unit 48. The widths of the coil unit 48 and the heating member 46 are also wider than the width of the planographic printing plate precursor 12.

The lower surface portion of the heating member 46 forms a part of the peripheral surface of the film guide 42, and the upper surface portion of the heating member 46 is closely contacted with the coil unit 48. The inner peripheral length of the heat resistant film 40 is a slightly longer than the outer peripheral length of the film guide 42 so that the heat resistant film 40 loosely covers the film guide 42, whereby a tension towards the outer peripheral of the film guide 42 is not generated.

A rod-shaped core metal 50 is provided in the axial portion of the pressurizing roller 44, and a thick cylindrical elastic layer 52 is fixed on the peripheral surface of the core metal 50. The elastic layer 52 is made of a rubber material having good release property such as silicone rubber. The pressurizing roller 44 revolves by torque from a driving motor (omitted in the drawing) connected to the core metal 50 at the same linear velocity as the conveying velocity of the planographic printing plate precursor 12 and pressurizes the heating member 46 via the heat resistant film 40. The pressurized portion N formed between the pressurizing roller 44 and the heating member 46 (see FIG. 4) is located on the conveyer pathway of the planographic printing plate precursor 12. Accordingly, the planographic printing plate precursor 12 passes through the pressurized portion N on the way from the outer drum 20 to the ejection tray 18 and heated (postheated) at the pressurized portion N by the post-heating apparatus 38. During this heating, the heat resistant film 40 moves circularly along the film guide 42 by the friction force from the planographic printing plate precursor 12.

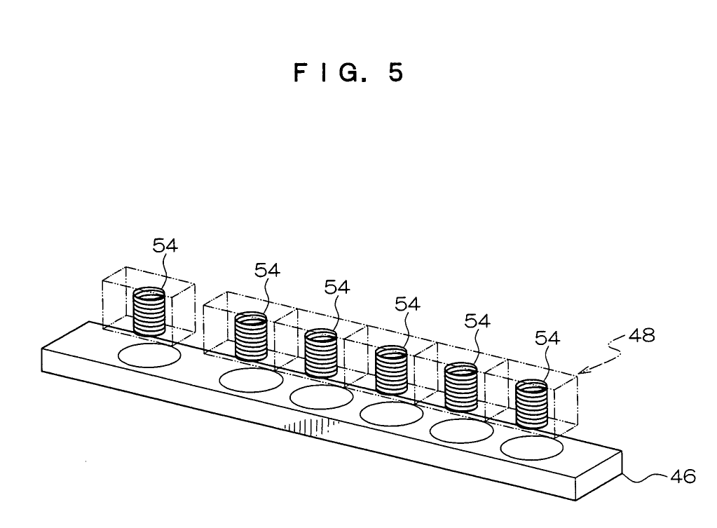

As shown in FIG. 5, the coil unit 48 includes plural excitation coils 54 aligned along the width direction of the planographic printing plate precursor 12, the excitation coils 54 are connected serially and the excitation coils 54 on the both ends are connected to a high frequency converter (omitted in the drawing) respectively. Accordingly, when the high frequency electric current output from the high frequency converter is applied on the excitation coils 54, high frequency magnetic field is generated from each of the excitation coils 54, and the high frequency magnetic field acts on the heating member 46. Accordingly, the heating member 46, which is made of a magnetic metal, is induction heated to generate calorie according to the strength of the high frequency magnetic field, the frequency of the high frequency electric current and the like. Therefore, the calorie applied on the planographic printing plate precursor 12 from the heating member 46 can be controlled by changing the waveform of the high frequency electric current applied on the excitation coils 54 by the high frequency converter (switching duty, frequency and the like) and controlling the power supply.

As shown in FIG. 1, in the image exposure device 10 is provided a temperature sensor 56 just behind the post-heating apparatus 38 along the feeding pathway, and the temperature sensor 56 detects the surface temperature of the planographic printing plate precursor 12 having passed the post-heating apparatus 38 and outputs the detected signal on the heat controlling portion (omitted in the drawing) of the apparatus. The heat controlling portion heats the planographic printing plate precursor 12 having passed the pressurized portion N to a predetermined post-heating temperature by feedback-controlling the high frequency converter based on the detected signal from the temperature sensor 56. In the post-heating apparatus 38, the lower surface portion of the heating member 46 is formed planerly. Accordingly, the heating member 46 is pressurized in surface-contacting with the planographic printing plate precursor 12 passing the pressurized portion N, while the lower surface portion of the heating member 46 may be formed to have curved surface and pressurized in substantially linearly-contacting with the planographic printing plate precursor 12.

### IMAGE EXPOSURE DEVICE ACCORDING TO THE SECOND EMBODIMENT

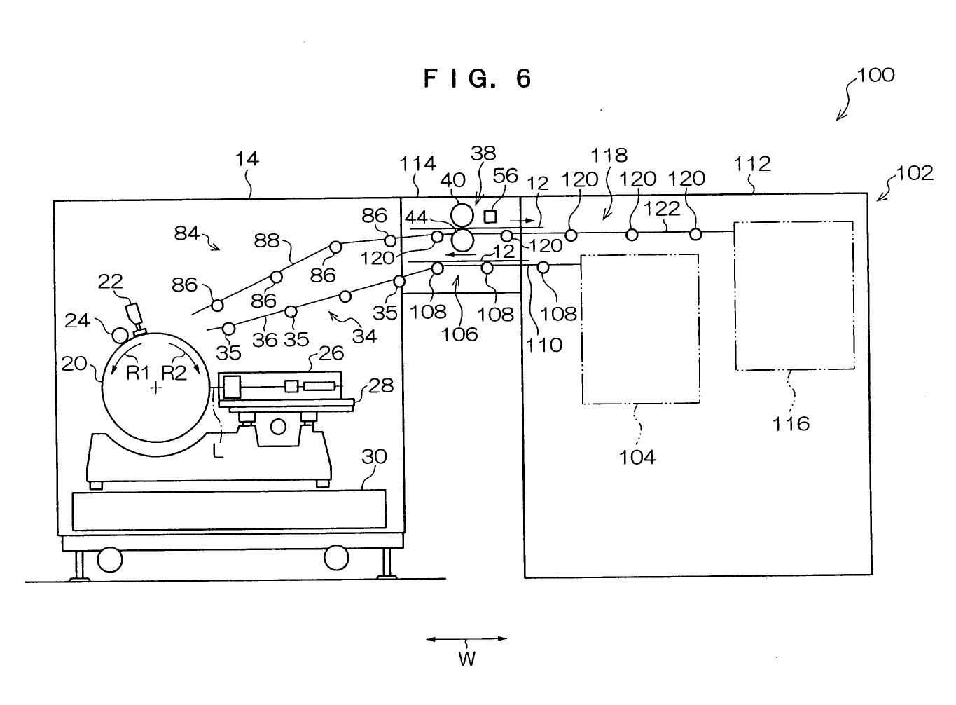

FIG. 6 shows the image exposure device according to the second embodiment of the invention. In the image exposure device 100 of the second embodiment, the portions being common with those of the image exposure device 10 of the first embodiment have the similar symbols and the explanations thereof are omitted.

The image exposure device 100, similarly to the image exposure device 10 of the first embodiment, carries out scanning-exposure of the planographic printing plate precursor 12 by IR laser L modulated based on a digital image information to form an image corresponding to the digital image information on the planographic printing plate precursor 12. As shown in FIG. 6, the differences of the image exposure device 100 from the image exposure device 10 are that the plate feeding stage 16 and the ejection tray 18 are omitted, an automatic loader 102 is added as an optional unit instead of these plate feeding stage 16 and ejection tray 18, and that the post-heating apparatus 38 is transferred from the body casing 14 to the automatic loader 102.

The automatic loader 102 supplies the planographic printing plate precursor 12 to the feeding mechanism 34 according to the control from the controlling portion of the image exposure device 100 (omitted in the drawing) or according to a predetermined supplying schedule, and accommodates the exposed planographic printing plate precursor 12. In the automatic loader 102 is provided a loader casing 112 as an outer shell portion, and the loader casing 112 are provided with a loading portion 104 in which a lot of planographic printing plate precursor 12 can be loaded, and a stack portion (receiving portion) 116 in which a lot of planographic printing plate precursor 12 can be accommodated.

The automatic loader 102 includes a separation mechanism (omitted in the drawing) for separating one planographic printing plate precursor 12 from the bundle of the planographic printing plate precursors 12 loaded in the loading portion 104, a first conveying mechanism 106 for conveying the one planographic printing plate precursor 12 separated by the separation mechanism to the body casing 14 and provides to the feeding mechanism 34, and a second conveying mechanism (means for conveying) 118 for conveying the planographic printing plate precursor 12 conveyed from the body casing 14 by the conveyer mechanism 84 to the stack portion 116.

The first conveying mechanism 106 is constituted by a conveyer roller 108, a guide member 110 and the like, which are provided along the conveying pathway that links the loading portion 104 and the inlet portion of the feeding mechanism 34, and the mechanism 106 conveys the planographic printing plate precursor 12 detached from the loading portion 104 to the conveying starting position by the feeding mechanism 34 at the conveying velocity. The second conveying mechanism 118 is constituted by the conveyer roller 120 and a guide member 122 and the like, which are provided along the conveying pathway that links the outlet portion of the conveyer mechanism 84 and the stack portion 116, and the mechanism 118 conveys the planographic printing plate precursor 12 ejected from the body casing 14 by the conveyer mechanism 84 and ejects the plate into the stack portion 116. The planographic printing plate precursor 12 ejected into the stack portion 116 is positioned at a predetermined location in the stack portion 116, and stacked on the bottom plate portion of the stack portion 116 or on the other planographic printing plate precursor 12 to constitute a bundle of the planographic printing plate precursors.

In the automatic loader 102 is provided a bridge-type connecting portion 114 that links the loader casing 112 to the body casing 14 of the image exposure device 100, and the conveying mechanisms 106 and 118 are connected to the feeding mechanism 34 and the conveyer mechanism 84 respectively in the body casing 14 via the connecting portion 114. In the automatic loader 102 is also provided a post-heating apparatus 38 for post-heating the planographic printing plate precursor 12 in the connecting portion 114, and the post-heating apparatus 38 heats the planographic printing plate precursor 12 conveyed by the second conveying mechanism 118 from the body casing 14 to the stack portion 116, to a predetermined post-heating temperature. The post-heating apparatus 38 of the second embodiment basically has the structure common with that of the post-heating apparatus of the first embodiment. However, in image exposure device 100, when the distance from the outer drum 20 to the post-heating apparatus 38 becomes longer and the period for conveying becomes longer, the post-heating temperature is sometimes needs to be set at a higher temperature than that for the image exposure device 10. Accordingly, for the heat generation of the post-heating apparatus 38, the design specification can be modified according to the degree of the post-heating temperature and the like.

In the image exposure device 100 of the second embodiment as constituted above, since the post-heating apparatus 38 is located on the automatic loader 102, which is an optional unit, the structure of the apparatus body of the image exposure device 100 is not different from conventional image exposure devices without post-heating apparatus 38 except that the feeding stage 16 and the ejection tray 18 are omitted. Accordingly, according to the image exposure device 100, the post-heating of planographic printing plate precursor 12 can be carried out by only adding the automatic loader 102 to a conventional image exposure device, whereby the costs and time periods for development of an image exposure device capable of post-heating can be reduced significantly. Furthermore, the image exposure devices those having been already delivered to users can be modified to those capable of post-heating by only addition of the automatic loader 102 and the like and easy modification of setting.

The post-heating apparatus 38 used for the image exposure devices 10 and 100 according to the invention heats (by indirect heating) the planographic printing plate precursor 12 by heating the heating member 46 to high temperature by magnetic induction so that heat transmission from the heating member 46 occurs. Alternatively, the substrate can be heated by heating (direct heating), without the heating member 46, by directly applying the high frequency magnetic field from the coil unit 48 on the substrate (aluminum plate) of the planographic printing plate precursor 12.

Alternatively, besides the post-heating apparatus 38 using magnetic induction heating as mentioned above, an apparatus for heating the planographic printing plate precursor by blowing air flow (blast) heated by a heater such as a halogen heater or a ceramic heater to the planographic printing plate precursor 12, an apparatus for heating the planographic printing plate precursor by irradiating the image recording layer of the planographic printing plate precursor 12 with electromagnetic wave (microwave) having a predetermined wavelength to resonate the substances in the image recording layer such as water, or an apparatus for heating the planographic printing plate precursor by irradiating the planographic printing plate precursor with infrared radiation can also be used.

During the above-mentioned electromagnetic wave heating, it is preferable to incorporate a component that can resonate with electromagnetic wave and can generate heat in the recording layer component for the sake of absorbing electromagnetic wave effectively and converting the electromagnetic wave to thermal energy. For example, when electromagnetic wave of 240 Hz that generally used is used, water corresponds to the component. Accordingly, the water holding property of the recording layer can be improved and heat can be generated effectively by incorporating a compound having water such as a hydrophilic resin or a water soluble compound in the recording layer component. Examples of the hydrophilic resin to be used include those described in the section of the hydrophilic resin below in the present specification. Among these, in view of improvement of the water holding property of the recording layer, preferable examples include polysaccharides such as gum arabic, soy gum, hydroxypropylcellulose and hydroxymethylcellulose, polymer compounds having hydroxyl group in the molecule such as polyacrylic acid, sodium polyacrylate, hydroxypropylacrylate and polyvinylalcohol, and low molecular compounds such as polyhydric alcohols such as sorbitol and glycerin.

The planographic printing plate precursor thus image-exposed and ejected from the image exposure device can be installed without any developing process using a liquid developer and can be printed using ink and dampening water by a conventional procedure. That is, the unexposed portion of the planographic printing plate precursor after exposure is easily removed by aqueous components in the dampening water or an oily component such as ink at the initial stage of the printing process to expose a hydrophilic surface of the substrate, and the dampening water attaches to the substrate to form a non-image portion, which is cured by exposure. Alternatively, the hydrophobic portion formed by fusion of particles forms an image portion capable of receiving ink.

Alternatively, these planographic printing plate precursors can be used for printing after developing process using water or a suitable aqueous solution as a liquid developer.

Since the planographic printing plate precursor on which an image has been formed according to the method of the invention has an image portion area that has been sufficiently cured by the heating process that follows the image exposure, and has superior strength of the image portion, high printing durability that has been a problem in a printing plate so-called a developing-on-press type planographic printing plate can be achieved and many sheets of finely-printed materials can be provided.

In addition, it will be obvious that the method of the invention can be applied to not only scanning exposure by infrared laser based on a digital data, but also to image exposure based on an analog data and to image exposure using lithfilm, so long as infrared radiation is used.

[Structure of the Image Exposure Device According to the Image Forming Method of the Second Aspect]

The image exposure device on which the image forming method according to the second aspect of the invention is preferably carried out is explained with referring to the drawings.

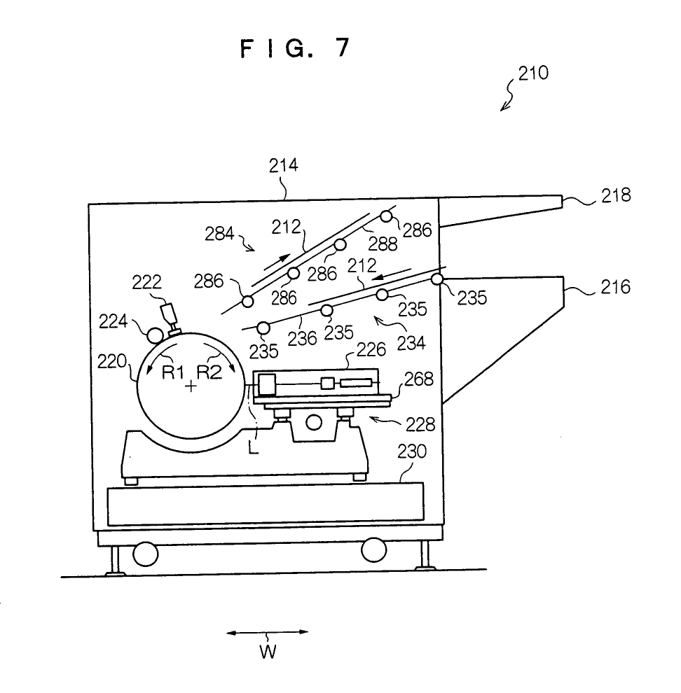

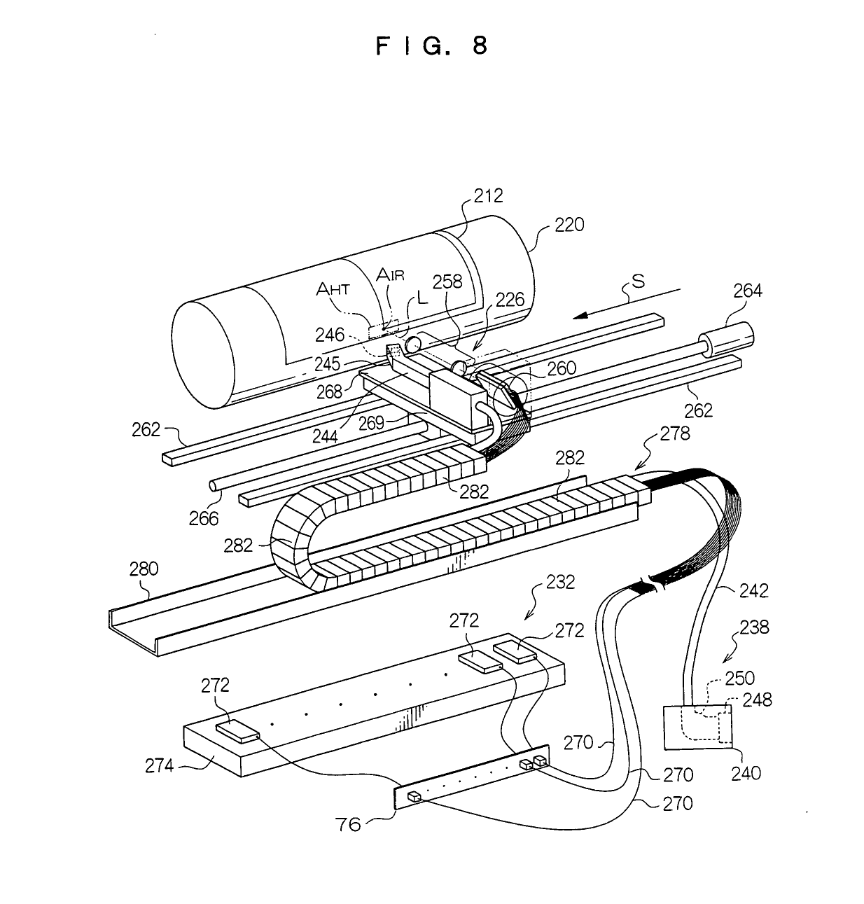

FIGS. 7 and 8 show the image exposure device according to the embodiment of the invention. In the image exposure device 210, a planographic printing plate precursor 212 is scanning-exposed by infrared laser L (hereinafter referred to as “IR laser L”) modulated by a digital image information, whereby an image (latent image) corresponding to the digital image information is formed on the planographic printing plate precursor 212. The planographic printing plate precursor 212 is called as a treatless printing plate since it requires no specific developing process. The planographic printing plate precursor includes a substrate made of aluminum or an aluminum alloy and an image recording layer formed on the substrate. The image recording layer (hereinafter, sometimes simply referred to as “recording layer”) may include a hydrophobic precursor and a light-to-heat converting agent; or it may include a polymerizable compound, a polymerization initiator and a light-to-heat converting agent. Hereinafter, the case wherein an image recording layer including microcapsules having heat reactive compound, a polymerization initiator and a light-to-heat converting agent, which is the first embodiment of the image recording layer, is used, is explained as an example.

As shown in FIG. 7, in the image exposure device 210 is provided a casing 214 as an outer shell portion of the apparatus. To the casing 214 is attached a plate feeding stage 216 for mounting a bundle of the planographic printing plate precursors 212 on one of the side plate portions along the width direction of the apparatus (direction of arrow W), and provided an ejection tray (receiving portion) 218 for ejecting the planographic printing plate precursor 212 having been exposed to the upper side of the plate feeding stage 216. In the casing 214 is rotatably provided a columnar outer drum (retention member) 220 to which one planographic printing plate precursor 212 is detachable. On the peripheral portion of the outer drum 220 are provided a chuck mechanism (retention member) 222 for chucking a tip portion and a back end portion of the planographic printing plate precursor 212 on the outer drum 220, and a guide roller 224 for winding the planographic printing plate precursor 212 on the peripheral surface of the outer drum 220.

In the casing 214 are provided an exposure head (means for exposing) 226 opposing to the outer drum 220 and a feeding mechanism (means for exposing) 228 for movably supporting the exposure head 226 along the sub-scanning direction. The exposure head 226 and the feeding mechanism 228 scanning-exposure the planographic printing plate precursor 212 attached on the outer drum 220 by the IR laser L modulated based on the digital image information to form an image corresponding to the digital image information on the planographic printing plate precursor 212. Furthermore, in the casing 214, a light source box 230 is provided on the lower side of the outer drum 220, and the light source box 230 accommodates an LD light source apparatus (means for exposing) 232 (see FIG. 8) for providing the IR laser L to the exposure head 226, and the like.

As shown in FIG. 7, in the image exposure device 210 is provided a feeding mechanism 234 for conveying the planographic printing plate precursor 212 mounted on the plate feeding stage 216 in the casing 214 to the outer drum 220. The feeding mechanism 234 includes plural conveyer rollers 235 provided along the feeding pathway of the planographic printing plate precursor 212 and a plate-shaped guide member 236. Furthermore, on the feeding mechanism 234 is provided a separation mechanism (omitted in the drawing) for separating one planographic printing plate precursor 212 from the bundle of the planographic printing plate precursors 212 stacked on the plate feeding stage 216 on the end of the plate feeding stage 216 and for providing the one planographic printing plate precursor 212 to the feeding pathway.

In the image exposure device 210, when the planographic printing plate precursor 212 is conveyed by the feeding mechanism 234 in the vicinity of the upper end portion of the outer drum 220, the tip portion of the planographic printing plate precursor 212 is chucked on the outer drum 220 by the chuck mechanism 222, and the outer drum 220 begins to rotate in a predetermined normal direction (direction of arrow R1 in FIG. 7). The planographic printing plate precursor 212 whose tip portion has been fixed on the outer drum 220 is wound on the peripheral surface of the outer drum 220 while the precursor 212 is pressurized to the surface of the outer drum 220 by the guide roller 224.

In the image exposure device 210, when the planographic printing plate precursor 212 has been wound on the outer drum 220 to the back end portion, the back end portion of the planographic printing plate precursor 212 is chucked on the outer drum 220 by the chuck mechanism 222. Accordingly, the planographic printing plate precursor 212 is entirely adhered on the peripheral surface of the outer drum 220, whereby the adhesion of the planographic printing plate precursor 212 on the outer drum 220 is completed. In the image exposure device 210, sub-scanning exposure of the planographic printing plate precursor 212 is carried out by moving the exposure head 226 in the sub-scanning direction by the feeding mechanism 228 in the state that the planographic printing plate precursor 212 had been adhered to the outer drum 220, and irradiating the planographic printing plate precursor 212 with the IR laser L irradiated from the exposure head 226. In the image exposure device 210, main scanning of the planographic printing plate precursor 212 can be carried out by revolving the outer drum 220 in the normal direction by revolution corresponding to the main scanning pitch in sync with the completion of one sub-scanning.

As shown in FIG. 8, on the exposure head 226 are provided a lens unit 258 composed of plural lenses, which constitute an image-forming optical system, and a fiber holder 260 including a pair of supporting plate holding tip portions of plural optical fibers 270 and a transparent protection plate for protecting the tip surfaces of the optical fibers 270 and the like. The exposure head 226 is mounted on a plate-shaped carrier 268, and moves along the sub-scanning direction (direction of arrow S of FIG. 8) with the carrier 268. The IR laser L each irradiated from the plural optical fibers 270 incidents in the lens unit 258, whereby the lens unit 258 forms an image on the planographic printing plate precursor 212 attached to the outer drum 220 to form a beam spot having a predetermined shape and size.

The exposure head 226 according to this embodiment is multi beam-type, which can project plural beam spots simultaneously on the planographic printing plate precursor 212. The plural beam spots are aligned along the sub-scanning direction of the planographic printing plate precursor 212, or aligned on a straight line being inclined slightly from the sub-scanning direction.

The feeding mechanism 228 includes a pair of guide rail 262, which supports the carrier 268 slidably along the sub-scanning direction and a screw axis 266 connected to a motor unit 264. On the lower surface portion of the carrier 268 is fixed a female screw member 269 having a screw hole in the sub-scanning direction, and the screw axis 266 is screwed in the female screw hole of the female screw member 269. Accordingly, when the screw axis 266 is rotated by the motor unit 264, the exposure head 226 moves, with the carrier 268, along the sub-scanning direction by a distance corresponding to the revolution of the screw axis 266 in the direction (forward direction or reverse direction) corresponding to the revolution direction of the screw axis 266. In the image exposure device 210 of this embodiment, the sub-scanning to the planographic printing plate precursor 212 is carried out only during the advancement of the exposure head 226.

As shown in FIG. 8, the other ends of the plural optical fibers 270 are connected to plural semiconductor lasers 272 in the LD light source portion 232 respectively. These semiconductor lasers 272 are fixed on a plate-shaped heat sink 274 of an LD light source apparatus 232. In the halfway of the optical fibers 270 is provided a connector array 276, and the optical fibers 270 are capable of connecting and disconnecting the portion on the fiber holder 260 and the portion on the semiconductor laser 272 via the connector array 276. Accordingly, for example, when any of semiconductor laser LDs breaks down, the broken semiconductor laser 272 can be readily changed without disassembling the fiber holder 260 and the like.

In the feeding mechanism 228 are provided a tubular cable bear 278 and a canaliculate bear guide 280 each extending in the sub-scanning direction under the guide rail 262. The cable bear 278 has a structure in which a number of link fragment 282 divided along the longitudinal direction are linked serially, the fragments can be curved along the vertical direction. In the cable bear 278 are inserted the exposure head 226 side portions of the optical fibers 270 (tip portions). The bear guide 280 support the cable bear 278 from below and limits the movement of the cable bear 278 in forward or backward direction. Accordingly, during the movement of the exposure head 226 in the sub-scanning direction, the tip side of the optical fibers 270 moving with the exposure head 226 is protected by the cable bear 278, whereby the damage on the optical fibers 270 is prevented.

In the image exposure device 210 is provided a post-heating apparatus (means for post-heating) 238 in a casing 214. The post-heating apparatus 238 heats (by spot-heating) the planographic printing plate precursor 212 locally by blast, and includes, as shown in FIG. 8, a heating fan unit (means for post-heating) 240 and a tubular blast nozzle (means for post-heating, heat supplying portion) 244 connected to the heating fan unit 240 via a flexible duct (means for post-heating) 242. The heating fan unit 240 is fixed on the casing 214, and the blast nozzle 244 and the exposure head 226 are mounted on a carrier 268. The tip portion of a flexible duct 242 and the bundle of optical fiber 270 are inserted in a cable bear 278.

The blast nozzle 244 is provided on the carrier 268 so as to be adjacent to the exposure head 226 at an upstream side along the sub-scanning direction. The blast nozzle 244 has a blow-off outlet 246 having a predetermined aperture form on the tip portion thereof, and the blow-off outlet 246 opens so as to oppose to the peripheral surface of an outer drum 220.

In the heating fan unit 240 are provided a heating portion 248 including a halogen heater, a ceramic heater or the like for heating the inlet air from outside of the casing 214, and a flue portion 250 for feeding the heated air in the flexible duct 242 with pressurizing. The air at high temperature fed in the flexible duct 242 is supplied to a blast nozzle 244, and is blown as a blast from the blow-off outlet 246 of the blast nozzle 244 to the planographic printing plate precursor 212 attached to the outer drum 220. The blast nozzle 244 is positioned adjacent to the exposure head 226 at an upstream side along the sub-scanning direction. The blast blown from the blow-off outlet 246 of the blast nozzle 244 is blown to an area (hereinafter sometimes referred to as “heating area A_{HT}”) adjacent to an area to which a beam spot of IR laser L is projected and exposed (hereinafter sometimes referred to as “exposure area A_{IR}”). The heating area A_{HT} is located at a downstream side of the exposure area A_{IR} on the planographic printing plate precursor 212 along the sub-scanning direction. The recording layer in the heating area A_{HT} is heated to a predetermined heating temperature.

The heating area A_{HT} has sufficiently larger size than those of the sub-scanning direction and the exposure area A_{IR} formed by a beam spot along the main scanning direction. Accordingly, the blast blown from the blast nozzle 244 heats the heating area A_{HT} including the exposure area A_{IR} immediately after the arbitrary exposure area A_{IR} on the planographic printing plate precursor 212 is exposed by the beam spot of IR laser L. On the image exposure device 210 is also provided a heat controlling portion (omitted in the drawing) for controlling the post-heating apparatus 238, wherein the heat controlling portion controls the temperature and flow of the blast supplied from the heating fan unit 240 to the blast nozzle 244 respectively, and maintains the temperature of the heating area A_{HT} on the planographic printing plate precursor 212 to the heating temperature.

In addition, a temperature sensor such as an infrared thermometer may be mounted on the carrier (carrier member) 268 so that the temperature of the heating area A_{HT} (surface temperature) is measured by the temperature sensor and that the measurement signal corresponding to the surface temperature of the heating area A_{HT} is output on the heat controlling portion. Accordingly, the temperature of the heating area A_{HT} can be feedback-controlled by the heat controlling portion based on the measurement signal, which allows fine and stable maintenance of the heating temperature of the heating area A_{HT}.

As shown in FIG. 7, in the casing 214 of the image exposure device 210 is provided a conveyer mechanism 284 for conveying the planographic printing plate precursor 212 detached from outer drum 220 to the ejection tray 218. The conveyer mechanism 284 includes plural conveyer rollers 286 provided along the conveyer pathway of the planographic printing plate precursor 212 and a plate-shaped guide member 288.

In the image exposure device 210, after the exposure (image-forming) on the planographic printing plate precursor 212 attached on the outer drum 220 is completed, the outer drum 220 is revolved in the reverse direction (direction of arrow R2 in FIG. 7) while the back end portion and the tip portion of the planographic printing plate precursor 212 are released sequentially from the outer drum 220 by the chuck mechanism 222. In conjunction with this, the conveyer mechanism 284 begins to convey the planographic printing plate precursor 212 that has been delivered from the outer drum 220 to the inlet portion of the conveyer pathway to the ejection tray 218 by revolving the conveyer roller 286, and the planographic printing plate precursor 212 is ejected on the ejection tray 218.

The post-heating apparatus 238 of the image exposure device 210 of the invention blows blast directly on the surface of the planographic printing plate precursor 212 to carry out spot-heating of the heating area A_{HT} on the planographic printing plate precursor 212. Such post-heating apparatus is not limited to the apparatus using blast, and spot-heating can be carried out by, for example, a method including mounting an infrared radiator (IR radiator) such as a halogen heater or a ceramic heater on a carrier 268 and irradiating the planographic printing plate precursor 212 with the infrared radiation from the IR radiator to carry out spot-heating of the heating area A_{HT}, or a method including mounting a magnetron on the carrier 268, irradiating the recording layer of the planographic printing plate precursor 212 with the electromagnetic wave having a predetermined wavelength generated by the magnetron to resonate substances in the recording layer such as water to carry out spot-heating (electromagnetic wave heating), or a method including mounting an electromagnetic coil on the carrier 268 and applying the high frequency magnetic field from the electromagnetic coil on a substrate made of metal on the planographic printing plate precursor 212 to carry out the spot-heating (induction heating) of the substrate.

During the above-mentioned electromagnetic wave heating, it is preferable to incorporate a component that can resonate with electromagnetic wave and can generate heat in the recording layer component for the sake of absorbing electromagnetic wave effectively and converting the electromagnetic wave to thermal energy. For example, when electromagnetic wave of 240 Hz that generally used is used, water corresponds to the component. Accordingly, the water holding property of the recording layer can be improved and heat can be generated effectively by incorporating a compound having water such as a hydrophilic resin or a water soluble compound in the recording layer component. Examples of the hydrophilic resin to be used include those described in the section of the hydrophilic resin below in the present specification. Among these, in view of improvement of the water holding property of the recording layer, preferable examples include polysaccharides such as gum arabic, soy gum, hydroxypropylcellulose and hydroxymethylcellulose, polymer compounds having hydroxyl group in a molecule such as polyacrylic acid, sodium polyacrylate, hydroxypropylacrylate and polyvinylalcohol, and low molecular compounds such as polyhydric alcohols such as sorbitol and glycerin.

The planographic printing plate precursor thus image-exposed and ejected from the image exposure device can be installed without any developing process using a liquid developer and can be printed using ink and dampening water by a conventional procedure. That is, the unexposed portion of the planographic printing plate precursor after exposure is easily removed by aqueous components in the dampening water or an oily component such as ink at the initial stage of the printing process to expose a hydrophilic surface of the substrate, and the dampening water attaches to the substrate to form a non-image portion, which is cured by exposure. Alternatively, the hydrophobic portion formed by fusion of particles forms an image portion capable of receiving ink.

Alternatively, these planographic printing plate precursors can be used for printing after developing process using water or a suitable aqueous solution as a liquid developer.

Since the planographic printing plate precursor on which an image has been formed according to the method of the invention has an image portion area having been sufficiently cured by the post-heating process, which has been carried out locally and efficiently, and has superior strength of the image portion, high printing durability that has been a problem in a printing plate so-called a developing-on-press type planographic printing plate can be achieved and many sheets of finely-printed materials can be provided.

In addition, it will be obvious that the method of the invention can be applied to not only scanning exposure by infrared laser based on a digital data, but also to image exposure based on an analog data so long as infrared radiation is used.

[Structure of the Image Exposure Device According to the Image Forming Method of the Third Aspect]

The image exposure device on which the image forming method according to the third aspect of the invention is preferably carried out is explained with referring to the drawings.

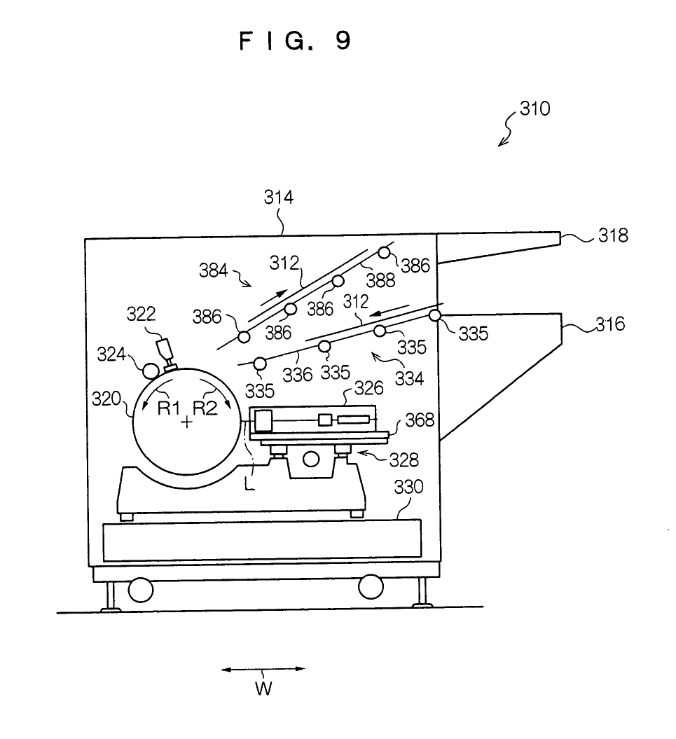

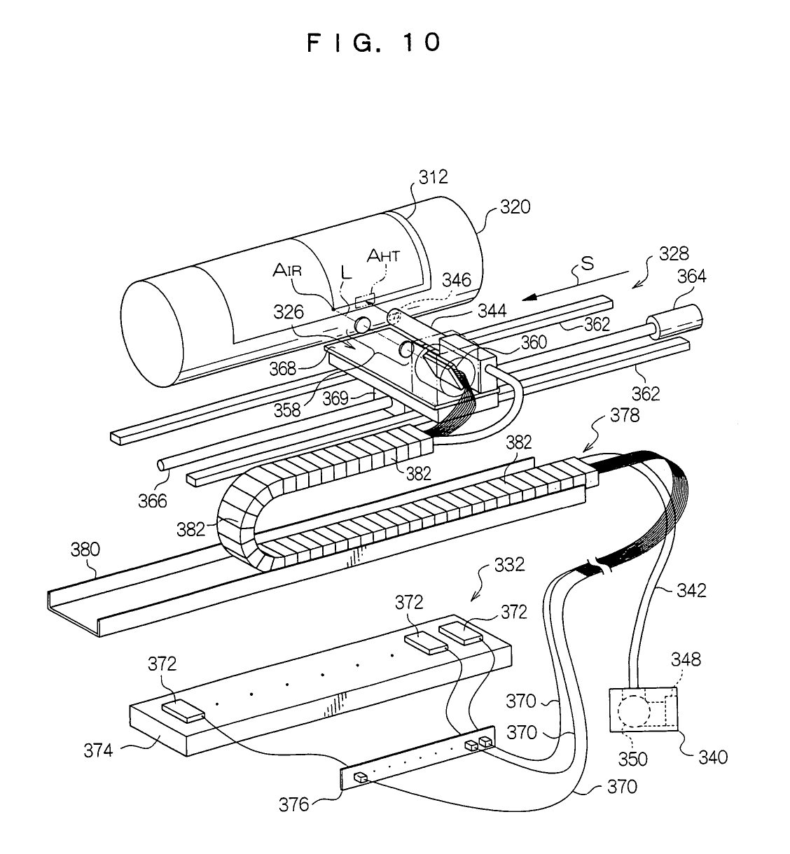

FIGS. 9 and 10 show the image exposure device according to the embodiment of the invention. In the image exposure device 310, the planographic printing plate precursor 312 is scanning-exposed by infrared laser L (hereinafter referred to as “IR laser L”) modulated by digital image information, whereby an image (latent image) corresponding to the digital image information is formed on the planographic printing plate precursor 312. The planographic printing plate precursor 312 is called as a treatless printing plate since it requires no specific developing process. The planographic printing plate precursor includes a substrate made of aluminum or an aluminum alloy and an image recording layer formed on the substrate. The image recording layer (hereinafter, sometimes simply referred to as “recording layer”) may include a hydrophobic precursor and a light-to-heat converting agent; or it may include a polymerizable compound, a polymerization initiator and a light-to-heat converting agent. These planographic printing plate precursors will be detailed later.

As shown in FIG. 9, in the image exposure device 310 is provided a casing 314 as an outer shell portion of the apparatus. The casing 314 is attached a plate feeding stage 316 for mounting a bundle of the planographic printing plate precursors 312 on one of the side plate portions along the width direction of the apparatus (direction of arrow W), and on the upper side of the plate feeding stage 316 is provided an ejection tray (receiving portion) 318 for ejecting the exposed planographic printing plate precursor 312. In the casing 314 is rotatably provided a columnar outer drum (retention member) 320 to which one planographic printing plate precursor 312 can be detached. On the peripheral portion of the outer drum 320 are provided a chuck mechanism (retention member) 322 for chucking a tip portion and a back end portion of the planographic printing plate precursor 312 on the outer drum 320, and a guide roller 324 for winding the planographic printing plate precursor 312 on the peripheral surface of the outer drum 320.

In the casing 314 are provided an exposure head (means for exposing) 326 opposing to the outer drum 320 and a feeding mechanism (means for exposing) 328 for movably supporting the exposure head 326 along the sub-scanning direction. The exposure head 326 and the feeding mechanism 328 scanning-exposure the planographic printing plate precursor 312 attached on the outer drum 320 by the IR laser L modulated based on the digital image information to form an image corresponding to the digital image information on the planographic printing plate precursor 312. Furthermore, in the casing 314, a light source box 330 is provided on the lower side of the outer drum 320, and the light source box 330 accommodates an LD light source apparatus (exposing means) 332 (see FIG. 10) for supplying IR laser L to the exposure head 326, and the like.

As shown in FIG. 9, in the casing 314 of the image exposure device 310 is provided a feeding mechanism 334 for conveying the planographic printing plate precursor 312 mounted on the plate feeding stage 316 to the outer drum 320. The feeding mechanism 334 includes plural conveyer rollers 335 provided along the feeding pathway of the planographic printing plate precursor 312 and a plate-shaped guide member 336. Furthermore, on the end of the plate feeding stage 316 of the feeding mechanism 334 is provided a separation mechanism (omitted in the drawing) for separating one planographic printing plate precursor 312 from the bundle of the planographic printing plate precursors 312 stacked on the plate feeding stage 316 and for providing the one planographic printing plate precursor 312 to the feeding pathway.

In the image exposure device 310, when the planographic printing plate precursor 312 is conveyed by the feeding mechanism 334 in the vicinity of the upper end portion of the outer drum 320, the tip portion of the planographic printing plate precursor 312 is chucked on the outer drum 320 by the chuck mechanism 322, and the outer drum 320 begins to rotate in a predetermined normal direction (direction of arrow R1 in FIG. 9). Accordingly, the planographic printing plate precursor 312 whose tip portion has been fixed on the outer drum 320 is wound on the peripheral surface of the outer drum 320 while the precursor 312 is pressurized to the surface of the outer drum 320 by the guide roller 324.

In the image exposure device 310, when the planographic printing plate precursor 312 has been wound on the outer drum 320 to the back end portion, the back end portion of the planographic printing plate precursor 312 is chucked on the outer drum 320 by the chuck mechanism 322. Accordingly, the planographic printing plate precursor 312 is entirely adhered on the peripheral surface of the outer drum 320, whereby the adhesion of the planographic printing plate precursor 312 on the outer drum 320 is completed. In the image exposure device 310, sub-scanning exposure of the planographic printing plate precursor 312 is carried out by moving the exposure head 326 in the sub-scanning direction by the feeding mechanism 328 in the state that the planographic printing plate precursor 312 adheres to the outer drum 320, and irradiating the planographic printing plate precursor 312 with the IR laser L irradiated from the exposure head 326. In the image exposure device 310, main scanning of the planographic printing plate precursor 312 can be carried out by revolving the outer drum 320 in the normal direction by revolution corresponding to the main scanning pitch in sync with the completion of one sub-scanning.

As shown in FIG. 10, on the exposure head 326 are provided a lens unit 358 composed of plural lenses, which constitute an image-forming optical system, and a fiber holder 360 including a pair of supporting plate holding tip portions of the plural optical fibers 370 and a transparent protection plate for protecting the tip surfaces of the optical fibers 370 and the like. The exposure head 326 is mounted on a plate-shaped carrier 368, and moves along the sub-scanning direction (direction of arrow S of FIG. 10) with the carrier 368. The IR laser L irradiated from the plural optical fibers 370 incident in the lens unit 358, whereby the lens unit 358 forms an image on the planographic printing plate precursor 312 attached to the outer drum 320 to form a beam spot having a predetermined shape and size. The exposure head 326 projects the beam spot from IR laser L to a predetermined area on the planographic printing plate precursor 312 (referred to as “exposure area A_{IR}”) The exposure area A_{IR} is moved in the sub-scanning direction and in the main scanning direction to form a two-dimensional image (latent image) on the planographic printing plate precursor 312.

The exposure head 326 according to this embodiment is multi beam-type, which can project plural beam spots simultaneously on the planographic printing plate precursor 312. The plural beam spots are aligned along the sub-scanning direction of the planographic printing plate precursor 312, or aligned on a straight line being inclined slightly from the sub-scanning direction.

The feeding mechanism 328 includes a pair of guide rail 362, which supports the carrier 368 slidably along the sub-scanning direction and a screw axis 366 connected to a motor unit 364. On the lower surface portion of the carrier 368 is fixed a block-shaped female screw member 369 having a screw hole, and the screw axis 366 is screwed in the female screw hole of the female screw member 369. Accordingly, when the screw axis 366 is rotated by the motor unit 364, the exposure head 326 moves, with the carrier 368, along the sub-scanning direction by a distance corresponding to the revolution of the screw axis 366 in the direction (forward direction or reverse direction) corresponding to the revolution direction of the screw axis 366. In the image exposure device 310 of this embodiment, although the sub-scanning to the planographic printing plate precursor 312 is carried out only during the advancement of the exposure head 326, the sub-scanning (reciprocate scanning) can be also carried out during advancement and retraction respectively.

As shown in FIG. 10, the other ends of the plural optical fibers 370 are connected to plural semiconductor lasers 372 in the LD light source portion 332 respectively. These semiconductor lasers 372 in an LD light source apparatus 332 are fixed on a plate-shaped heat sink 374. In the halfway of the optical fibers 370 is provided a connector array 376, and the optical fibers 370 are capable of connecting and disconnecting the portion on the fiber holder 360 and the portion on the semiconductor laser 372 via the connector array 376. Accordingly, for example, when any of semiconductor laser LDs breaks down, the broken semiconductor laser 372 can be readily changed without disassembling the fiber holder 360 and the like.

In the feeding mechanism 328 are provided a tubular cable bear 378 and a canaliculate bear guide 380 each extending in the sub-scanning direction under the guide rail 362. The cable bear 378 has a structure in which a number of link fragment 382 divided along the longitudinal direction are linked serially, the fragments can be curved along the vertical direction. In the cable bear 378 are inserted the portion at the side of the exposure head 326 of the optical fibers 370 (tip portions). The bear guide 380 support the cable bear 378 from below and limits the movement of the cable bear 378 in forward or backward direction. Accordingly, during the movement of the exposure head 326 in the sub-scanning direction, the tip side of the optical fibers 370 moving with the exposure head 326 is protected by the cable bear 378, whereby the damage on the optical fibers 370 is prevented.

In the image exposure device 310 is provided a heating apparatus (means for heating) 338 in a casing 314. The heating apparatus 338 heats (by spot-heating) the planographic printing plate precursor 312 locally by blast. The heating apparatus 338 includes, as shown in FIG. 10, a heating fan unit (means for heating) 340 and a tubular blast nozzle (means for heating) 344 connected to the heating fan unit 340 via a flexible duct 342. The heating fan unit 340 is fixed on the casing 314, and the blast nozzle 344 and the exposure head 326 are mounted on a carrier 368. The tip portion of a flexible duct 342 and the bundle of optical fiber 370 are inserted in a cable bear 378.

The blast nozzle 344 is provided on the carrier 368 so as to be adjacent to the exposure head 326 along the sub-scanning direction. The blast nozzle 344 is supported so that the rear anchor side thereof extends parallel to the traveling direction of the IR laser L, and the tip portion thereof has a bend portion 345 that has been bent to direct the exposure area A_{IR} on the planographic printing plate precursor 312 from the rear anchor side to the tip surface. On the tip surface of the bend portion 345 is provided a blow-off outlet 346 having a rectangular aperture.

In the heating fan unit 340 are provided a heating portion 348 including a halogen heater, a ceramic heater or the like for heating the inlet air from outside of the casing 314, and a flue portion 350 for feeding the heated air in the flexible duct 342 with pressurizing. The air at high temperature fed in the flexible duct 342 is supplied to a blast nozzle 344, and is blown as a blast from the blow-off outlet 346 of the blast nozzle 344 to the planographic printing plate precursor 312 attached to the outer drum 320. Since the bend portion 345 of the blast nozzle 344 directs to the exposure area A_{IR} on the planographic printing plate precursor 312, the blast from the blow-off outlet 346 is blown to the area overlapped with the exposure area A_{IR} on the planographic printing plate precursor 312 (sometimes referred to as “heating area A_{HT}”) to heat the recording layer in the heating area A_{HT} to a predetermined heating temperature.

The center of the heating area A_{HT} is approximately identical with the center of the exposure area A_{IR}, and the heating area A_{HT} has sufficiently larger size than that of the exposure area A_{IR} along the sub-scanning direction and the main scanning direction. Accordingly, the heating area A_{HT} on the planographic printing plate precursor 312 becomes an area including the exposure area A_{IR}, and the blast blown from the blow-off outlet 346 is blown to the heating area A_{HT} including the exposure area A_{IR}, simultaneously with the irradiation of the arbitrary exposure area A_{IR} on the planographic printing plate precursor 312, to heat the heating area A_{HT} to a predetermined temperature during from the initiation of the exposure of the exposure area A_{IR} by laser L to the completion of the exposure.

The exposure period during from the initiation of the exposure of the exposure area A_{IR} by IR laser L to the completion of the exposure is approximately identical with the modulation frequency of the IR laser L according to the sub-scanning velocity, and is generally such short period as 0.05 seconds. In order to heat the planographic printing plate precursor 312 to the desired heating temperature by blast within such short period, the temperature of blast should be remarkably high and which is not practical. Accordingly, it is preferable that the heating area A_{HT} has a length being 50 to 100-folds longer than that of the exposure area A_{IR} along the sub-scanning direction so that the blast heating to the arbitrary exposure area A_{IR} in the heating area A_{HT} can be continued for a period being 10⁶ to 10⁷-folds or more longer than the modulation frequency. Accordingly, the heating period to the arbitrary exposure area A_{IR} can be extended sufficiently, which allows stable heating of the exposure area A_{IR} to a predetermined heating temperature without raising the blast temperature to remarkably high temperature.

On the image exposure device 310 is provided a heat controlling portion (omitted in the drawing) for controlling the post-heating apparatus 338, wherein the heat controlling portion controls the temperature and flow of the blast supplied from the heating fan unit 340 to the blast nozzle 344 respectively. In addition, a temperature sensor such as an infrared thermometer may be mounted on the carrier (carrier member) 368 so that the temperature of the heating area A_{HT} (surface temperature) is measured by the temperature sensor and that the measurement signal corresponding to surface temperature of the heating area A_{HT} is output on the heat controlling portion. Accordingly, the temperature of the central portion of the heating area A_{HT} can be feedback-controlled by the heat controlling portion according to the measurement signal, which allows fine and stable maintenance of the heating temperature of the heating area A_{HT}.

As shown in FIG. 9, in the casing 314 of the image exposure device 310 is provided a conveyer mechanism 384 for conveying the planographic printing plate precursor 312 detached from outer drum 320 to the ejection tray 318. The conveyer mechanism 384 includes plural conveyer rollers 386 provided along the conveyer pathway of the planographic printing plate precursor 312 and a plate-shaped guide member 388.

In the image exposure device 310, after the exposure (image-forming) on the planographic printing plate precursor 312 attached on the outer drum 320 is completed, the outer drum 320 is revolved in the reverse direction (direction of arrow R2 in FIG. 9) while the back end portion and the tip portion of the planographic printing plate precursor 312 are released sequentially from the outer drum 320 by the chuck mechanism 322. In conjunction with this, the conveyer mechanism 384 begins to convey the planographic printing plate precursor 312 that has been delivered from the outer drum 320 to the inlet portion of the conveyer pathway to the ejection tray 318 by revolving the conveyer roller 386, and the planographic printing plate precursor 312 is ejected on the ejection tray 318.

The heating apparatus 338 of the image exposure device 310 of the invention blows blast directly on the surface of the planographic printing plate precursor 312 to carry out spot-heating of the heating area A_{HT} on the planographic printing plate precursor 312. Such heating apparatus is not limited to the apparatus using blast, and spot-heating can be carried out by, for example, a method including mounting an infrared radiator such as a halogen heater or a ceramic heater on a carrier 368 and irradiating the planographic printing plate precursor 312 with the infrared radiation from the IR radiator to carry out spot-heating of the heating area A_{HT}, or a method including mounting a magnetron on the carrier 368, irradiating the recording layer of the planographic printing plate precursor 312 with the electromagnetic wave having a predetermined wavelength generated by the magnetron to resonate substances in the recording layer such as water to carry out spot-heating (electromagnetic wave heating), or a method including mounting an electromagnetic coil on the carrier 368 and applying the high frequency magnetic field from the electromagnetic coil on a substrate made of metal on the planographic printing plate precursor 312 to carry out spot-heating (induction heating) of the substrate.

During the above-mentioned electromagnetic wave heating, it is preferable to incorporate a component that can resonate with electromagnetic wave and can generate heat in the recording layer component for the sake of absorbing electromagnetic wave effectively and converting the electromagnetic wave to thermal energy. For example, when electromagnetic wave of 240 Hz that generally used is used, water corresponds to the component. Accordingly, the water holding property of the recording layer can be improved and heat can be generated effectively by incorporating a compound having water such as a hydrophilic resin or a water soluble compound in the recording layer component. Examples of the hydrophilic resin to be used include those described in the section of the hydrophilic resin below in the present specification. Among these, in view of improvement of the water holding property of the recording layer, preferable examples include polysaccharides such as gum arabic, soy gum, hydroxypropylcellulose and hydroxymethylcellulose, polymer compounds having hydroxyl group in a molecule such as polyacrylic acid, sodium polyacrylate, hydroxypropylacrylate and polyvinylalcohol, and low molecular compounds such as polyhydric alcohols such as sorbitol and glycerin.

The planographic printing plate precursor thus image-exposed and ejected from the image exposure device can be installed without any developing process using a liquid developer and can be printed using ink and dampening water by a conventional procedure. That is, the unexposed portion of the planographic printing plate precursor after exposure is easily removed by aqueous components in the dampening water or an oily component such as ink at the initial stage of the printing process to expose a hydrophilic surface of the substrate, and the dampening water attaches to the substrate to form a non-image portion, which is cured by exposure. Alternatively, the hydrophobic portion formed by fusion of particles forms an image portion capable of receiving ink.

Alternatively, these planographic printing plate precursors can be used for printing after developing process using water or a suitable aqueous solution as a liquid developer.

Since the planographic printing plate precursor on which an image has been formed according to the method of the invention has an image portion area having been sufficiently cured by the heating process that has been carried out locally and efficiently, and has superior strength of the image portion, high printing durability that has been a problem in a printing plate so-called a developing-on-press type planographic printing plate can be achieved and many sheets of finely-printed materials can be provided.

In addition, it will be obvious that the method of the invention can be applied to not only scanning exposure by infrared laser based on a digital data, but also to image exposure based on an analog data so long as infrared radiation is used.

(Structure of Planographic Printing Plate Precursor)

Secondly, the structure of the planographic printing plate precursor capable of forming an image without liquid development process, which can be preferably used for the image forming methods of the first to third aspects of the invention, is explained in detail.

-Image Recording Layer Including Hydrophobic Precursor and Light-to-Heat Converting Agent-

An image recording layer including a hydrophobic precursor and a light-to-heat converting agent is characterized in forming a hydrophobic portion (an image portion) due to energy of image exposure.

As an image recording layer including a hydrophobic precursor and a light-to-heat converting agent preferably applicable to first to third aspect of planographic printing plate precursor, the following first to third embodiments of image recording layers may be used.

[Image Recording Layer Including (a) Aicrocapsules Including a Compound Having a Heat Reactive Group and a Light-to-Heat Converting Agent]

The planographic printing plate precursor according to the first embodiment is characterized in that it includes, on a substrate, a material including (a) microcapsules including a compound having a heat reactive group as a hydrophobic precursor capable of forming a surface hydrophobic portion by heat. When the heat reactive group included in the heat reactive compound is a polymerizable group, the image recording layer preferably includes a polymerization initiator that generates a reaction initiator (active species) due to energy of image exposure.

The polymerization initiator and the light-to-heat converting agent may be added to at least in the recording layer matrix, i.e., in the microcapsules or out of the microcapsules. In view of store stability, the polymerization initiator is preferably added to the recording layer matrix, and the light-to-heat converting agent is preferably added to the microcapsules in view of the sensitivity.

((a) Microcapsules Including a Compound Having a Heat Reactive Group)

Examples of the heat reactive group in the heat reactive compound according to the first embodiment used in the invention include, as the functional groups common with the functional groups for the (c) microparticle polymer having a heat reactive group mentioned below, ethylenically unsaturated groups for radical polymerization reaction (for example, acryloyl group, methacryloyl group, vinyl group, allyl group); cationic polymerization groups (for example, vinyl group, vinyloxy group and epoxy group); isocyanate group or block form thereof for addition reaction, and functional groups having active hydrogen atom, which is a reaction partner therefor (for example, amino group, hydroxyl group, carboxyl group). Similarly, epoxy group for addition reaction, and amino group, carboxyl group or hydroxyl group, which is a reaction partner therefor; carboxyl group for condensation reaction and hydroxyl group or amino group; acid anhydride for ring-opening addition reaction and amino group or hydroxyl group, can be exemplified. The heat reactive group used for the invention is not specifically limited to these, and any functional group can be used so long as it forms a chemical bond. Typical examples of the heat reactive compound include cationic polymerizable compounds and radical polymerizable compounds.

<Cationic Polymerizable Compound>

The cationic polymerizable compound used for the invention is not specifically limited so long as it is a compound having cationic polymerizable group in a molecule. Among these, compounds having vinyloxy group or epoxy group are preferably used.

The cationic polymerizable compound having vinyloxy group preferred for the invention includes, for example, compounds disclosed in JP-A No. 2002-29162.

Specific examples thereof include, but not limited to, tetramethyleneglycol divinylether, trimethylolpropane trivinylether, tetraethyleneglycol divinyl ether, pentaerithritol divinyl ether, pentaerithritol trivinyl ether, pentaerithritol tetravinyl ether, 1,4-bis{2-(vinyloxy)ethyloxy}benzene, 1,2-bis{2-(vinyloxy)ethyloxy}benzene, 1,3-bis{2-(vinyloxy)ethyloxy}benzene, 1,3,5-tris{2-(vinyloxy)ethyloxy}benzene, 4,4′-bis{2-(vinyloxy)ethyloxy}biphenyl, 4,4′-bis{2-(vinyloxy)ethyloxy}diphenylether, 4,4′-bis{2-(vinyloxy)ethyloxy}diphenylmethane, 1,4-bis{2-(vinyloxy)ethyloxy}naphthalene, 2,5-bis{2-(vinyloxy)ethyloxy}furan, 2,5-bis{2-(vinyloxy)ethyloxy}thiophene, 2,5-bis{2-(vinyloxy)ethyloxy}imidazole, 2,2-bis[4-{2-(vinyloxy)ethyloxy}phenyl]propane, bis(vinyloxyethyl)ether of bisphenol A, 2,2-bis{4-(vinyloxymethyloxy)phenyl}propane and 2,2-bis{4-(vinyloxy)phenyl}propane. Of these, 2,2-bis[4-{2-(vinyloxy)ethyloxy}phenyl]propane, bis(vinyloxyethyl)ether of bisphenol A, 2,2-bis{4-(vinyloxymethyloxy)phenyl}propane, 2,2-bis{4-(vinyloxy)phenyl}propane are especially preferred.

The cationic polymerizable compound having epoxy group preferable for the invention preferably includes a compound having two or more of epoxy groups such as a glycidylether compound obtained by the reaction of a polyhydric alcohol or a polyhydric phenol with epichlorohydrin or a prepolymer thereof, and a polymer or a copolymer of glycidyl acrylate or glycidyl methacrylate.

Specific examples thereof include, but not limited to, propyleneglycol diglycidylether, tripropyleneglycol diglycidylether, polypropyleneglycol diglycidylether, neopentylglycol diglycidylether, trimethylolpropane triglycidylether, diglycidylether of hydrogenated bisphenol A, hydroquinone diglycidylether, resorcinol diglycidylether, diglycidylether or epichlorohydrin polyadduct of bisphenol A, diglycidylether or epichlorohydrin polyadduct of bisphenol F, diglycidylether or epichlorohydrin polyadduct of halogenated bisphenol A, diglycidylether or epichlorohydrin polyadduct of biphenyl type bisphenol and glycidyletherated product of novolak resin, and methyl methacrylate/glycidyl methacrylate copolymer and ethyl methacrylate/glycidyl methacrylate copolymer. Among these, diglycidylether or epichlorohydrin polyadduct of bisphenol A, diglycidylether or epichlorohydrin polyadduct of halogenated bisphenol A, diglycidylether or epichlorohydrin polyadduct of biphenyl type bisphenol are especially preferred.

Commercial products of the above-mentioned compounds include, for example, EPICOAT 1001 (molecular weight about 900, epoxy equivalent 450 to 500), EPICOAT 1002 (molecular weight about 1600, epoxy equivalent 600 to 700), EPICOAT 1004 (about 1060, epoxy equivalent 875 to 975), EPICOAT 1007 (molecular weight about 2900, epoxy equivalent 2000), EPICOAT 1009 (molecular weight about 3750, epoxy equivalent 3000), EPICOAT 1010 (molecular weight about 5500, epoxy equivalent 4000), EPICOAT 1100L (epoxy equivalent 4000) and EPICOAT YX31575 (epoxy equivalent 1200) manufactured by Japan Epoxy Resin Co., Ltd., and SUMIEPOXY ESCN-195XHN, ESCN-195XL and ESCN-195XF manufactured by Sumitomo Chemical Co. Ltd.

<Radical Polymerizable Compound>

The radical polymerizable compound used for the invention is not specifically limited so long as it has ethylenically unsaturated bond in a molecule.

The functional group including ethylenically unsaturated bond (hereinafter referred to as ethylenically unsaturated group) includes, for example, acryloyl group, methacryloyl group, vinyl group and allyl group, and a compound having them at least one, preferably two or more is preferably used. Such compounds are widely known in the art as a monomer or a crosslinking agent for a radical polymerizable compound, and these compounds can be used without specific limitation for the invention. The chemical form include monomer, prepolymer (namely, dimer, trimer, oligomer), polymer or copolymer, or a mixture thereof.

The radical polymerizable compound preferable for the invention includes compounds having ethylenically unsaturated group disclosed in JP-A No. 2001-277740.

Typical examples include additives of trimethylolpropane di(meth)acrylate, trimethylolpropane tri(meth)acrylate, pentaerithritol di(meth)acrylate, pentaerithritol tri(meth)acrylate, pentaerithritol tetra(meth)acrylate, dipentaerithritol di(meth)acrylate, dipentaerithritol penta(meth)acrylate, dipentaerithritol hexa(meth)acrylate or trimethylolpropane diacrylate and xylylenediisocyanate.

The polymer or copolymer form of the compound having ethylenically unsaturated group includes, but not limited to, for example, copolymer of allyl methacrylate, allyl methacrylate/methacrylic acid copolymer, allyl methacrylate/ethylmethacrylate copolymer and allyl methacrylate/butylmethacrylate copolymer. Among these, dipentaerithritol tetracrylate, allyl methacrylate/methacrylic acid copolymer are specifically preferred.

<Other Heat Reactive Compound>

The content of the microcapsules for the invention may includes other compounds having a heat reactive group, as mentioned above, besides the above heat polymerizable compound.

Examples of the heat reactive group include isocyanate group for addition reaction and block form thereof, and functional group having active hydrogen atom, which is a reaction partner of the cationic polymerizable group or the ethylenically unsaturated group (for example, amino group, hydroxyl group and carboxyl group); carboxyl group for condensation reaction and hydroxyl group or amino group, which is a reaction partner therefor; and acid anhydride for ring-opening addition reaction and hydroxyl group or amino group, which is a reaction partner therefor.

The compound having isocyanate group preferable for the invention can include tolylenediisocyanate, diphenylmethanediisocyanate, polymethylenepolyphenylpolyisocyanate, xylylenediisocyanate, naphthalenediisocyanate, cyclohexanephenylenediisocyanate, isophoronediisocyanate, hexamethylenediisocyanate, cyclohexyldiisocyanate, or compounds obtained by blocking these with alcohol or amine.

The compound having amino group preferable for the invention includes ethylenediamine, diethylenetriamine, triethylenetetramine, hexamethylenediamine, propylenediamine and polyethyleneimine.

The compound having hydroxyl group preferable for the invention can include compounds having end methylol group, polyhydric alcohols such as pentaerithritol and bisphenol-polyphenols.

The compound having carboxyl group preferable for the invention includes aromatic polyhydric carboxylic acids such as pyromellitic acid, trimellitic acid and phthalic acid, aliphatic polyhydric carboxylic acids such as adipic acid.

The acid anhydride preferable for the invention includes pyromellitic anhydride and benzophenonetetracarboxylic anhydride.

The image recording layer according to the first embodiment of the invention needs to include a light-to-heat converting agent and a polymerization initiator in at least one of the microcapsules and the recording layer matrix. During addition of these components to microcapsules, these components are provided as a solution or a dispersion in the same solvent as for the above contents. The light-to-heat converting agent and the polymerization initiator, which can be used for the invention, are explained below.

As the method for microcapsulizing the above components, a known method can be applied. The method for producing microcapsules includes, but not limited to, for example, methods utilizing coacelvation as disclosed in U.S. Pat. Nos. 2,800,457 and 2,800,458; methods by interface polymerization as disclosed in U.K. Patent No. 990443 and U.S. Pat. No. 3,287,154, Japanese Patent Application Publication (JP-B) Nos. 38-19574, 42-446 and 42-711; methods by precipitation of a polymer as disclosed in U.S. Pat. Nos. 3,418,250 and 3,660,304; a method using an isocyanatepolyol wall material as disclosed in U.S. Pat. No. 3,796,669; a method using an isocyanate wall material as disclosed in U.S. Pat. No. 3,914,511; methods using a urea-formaldehyde or urea formaldehyde-resorcinol wall forming material as disclosed in U.S. Pat. Nos. 4,001,140, 4,087,376, 4,089,802; methods using wall materials such as melamine-formaldehyde resin or hydroxycellulose as disclosed in U.S. Pat. No. 4,025,445; in situ methods by polymerization of a monomer as disclosed in JP-B Nos. 36-9163 and 51-9079; spray drying methods as disclosed in U.K. Patent No. 930422 and U.S. Pat. No. 3,111,407; electrolyze dispersion cooling method as disclosed in U.K. Patent Nos. 952807 and 967074.

Preferred wall material for the microcapsules used for the invention is a material that swells in a coating solvent and can form three dimensional crosslinking. In view of this, the wall material for the microcapsules is preferably polyurea, polyurethane, polyester, polycarbonate, polyamide, and a mixture thereof, specifically preferably polyurea and polyurethane. A compound having a heat reactive group can be introduced in the microcapsule wall.

The average particle size of the obtained microcapsules is preferably 0.01 to 3.0 μm, more preferably 0.05 to 2.0 μm, and specifically preferably 0.10 to 1.0 μm. In this range, good resolution and stability for a long time can be obtained.

The microcapsules for the image forming method according to the first aspect, the capsule wall material collapses or becomes permeable by heat, which leads release of the polymerizable compound contained in the capsules to the reaction system, activation of the curing agent and proceeding of the reaction. However, when the post-heating temperature in the above-mentioned post-heating process reaches to the temperature in which the capsule wall material becomes permeable, undesired curing generates in the non-image portion and easily causes contamination, the upper limit of the post-heating temperature is preferably a temperature being less than the temperature in which the capsule wall material becomes permeable, preferably a temperature being 30° C. less than the temperature in which the capsule wall material becomes permeable. The temperature in which the capsule wall material becomes permeable differs depending on the substance that forms the capsule wall material and the thickness of the wall material, and for example, it is about 286° C. when an additive of trimethylolpropane and xylylenediisocyanate is used as a microcapsule wall material, or about 278° C. when a reaction product of an additive of trimethylolpropane and xylylenediisocyanate, MILLIONATE MR-200 (aromatic isocyanate manufactured by Japan Polyurethane Co., Ltd.), and tetraethylenepentamine is used as a microcapsule wall material.

The microcapsules for the image forming method according to the second aspect, the capsule wall material collapses or becomes permeable by heat, which leads release of the polymerizable compound contained in the capsules to the reaction system, activation of the curing agent and proceeding of the reaction. However, when the post-heating temperature in the above-mentioned post-heating process reaches to the temperature in which the capsule wall material becomes permeable, undesired curing agent generates in the non-image portion and easily causes contamination, the upper limit of the post-heating temperature is preferably a temperature being less than the temperature in which the capsule wall material becomes permeable, preferably a temperature being 30° C. less than the temperature in which the capsule wall material becomes permeable. The temperature in which the capsule wall material becomes permeable differs depending on the substance that forms the capsule wall material and the thickness of the wall material, and for example, it is about 286° C. when an additive of trimethylolpropane and xylylenediisocyanate is used as a microcapsule wall material, or about 278° C. when a reaction product of an additive of trimethylolpropane and xylylenediisocyanate, MILLIONATE MR-200 (aromatic isocyanate manufactured by Japan Polyurethane Co., Ltd.), and tetraethylenepentamine is used as a microcapsule wall material.

The microcapsules for the image forming method according to the third aspect, the capsule wall material collapses or becomes permeable by heat, which leads release of the heat reactive compound contained in the capsules to the reaction system, activation of the curing agent and proceeding of the reaction. However, when the heating temperature in the above-mentioned heating process reaches to the temperature in which the capsule wall material becomes permeable, undesired curing agent generates in the non-image portion and easily causes contamination, the upper limit of the post-heating temperature is preferably a temperature being less than the temperature in which the capsule wall material becomes permeable, preferably a temperature being 30° C. less than the temperature in which the capsule wall material becomes permeable. The temperature in which the capsule wall material becomes permeable differs depending on the substance that forms the capsule wall material and the thickness of the wall material, and for example, it is about 286° C. when an additive of trimethylolpropane and xylylenediisocyanate is used as a microcapsule wall material, or about 278° C. when a reaction product of an additive of trimethylolpropane and xylylenediisocyanate, MILLIONATE MR-200 (aromatic isocyanate manufactured by Japan Polyurethane Co., Ltd.), and tetraethylenepentamine is used as a microcapsule wall material.

In the microcapsules for the image forming methods according to the first to third aspects, the capsules may be coalesced by heat or may not be coalesced. That is, the content of microcapsule may be eluted on the surface or outside of microcapsules by image exposure to cause curing reaction. Especially, when the heat reactive compound is the polymerizable compound, the polymerizable compound eluted on the surface or outside of microcapsules cause a chemical reaction with a reaction initiator (active species) generated from a polymerization initiator, which will be detailed below. Alternatively, the reaction initiator may enter the microcapsule wall to cause a chemical reaction with the polymerizable compound. Furthermore, the polymerizable compound may react with a hydrophilic resin, which is added to the recording layer as an optional component or a low molecular compound. Microcapsules may be reacted each other by providing different functional groups those react by heat each other. Therefore, melt coalescence of the microcapsules by heat is preferable for image formation, but is not essential.

The amount to be added of the microcapsules to the recording layer is preferably not less than 50% by mass, and more preferably 70 to 98% by mass, based on the whole solid content in the image recording layer. In this range, good image can be formed and good printing durability can be obtained.

A solvent that can dissolve contents in the microcapsules and can swell the wall material can be added to the microcapsule dispersant in the recording layer including microcapsules. By adding such solvent, diffusion of contents in the microcapsules outside of the capsules can be accelerated during image exposure.

Such solvent can be readily selected from many commercially available solvents depending on the microcapsule dispersant, the material used in the microcapsule wall, wall thickness and the contents. For example, in the case of water dispersible microcapsule consisting of a crosslinking polyurea and a polyurethane wall, alcohols, ethers, acetals, esters, ketones, polyhydric alcohols, amides, amines and aliphatic acids are preferred.

Specific compounds include, but not limited to, methanol, ethanol, tert-butanol, n-propanol, tetrahydrofuran, methyl lactate, ethyl lactate, methylethylketone, propyleneglycol monomethylether, ethyleneglycol diethylether, ethyleneglycol monomethylether, γ-butyrolactone, N,N-dimethylformamide and N,N-dimethylacetoamide. Alternatively, two or more of these solvents can be used in combination. A solvent that does not dissolve in the microcapsule dispersant solely but dissolve by mixing the above solvent can be also used.

The amount to be added of such solvent is determined by the combination of the materials, and 5 to 95% by mass of the recording layer coating solution is effective, and the preferable range is 10 to 90% by mass, more preferable range is 15 to 85% by mass.

(Light-to-Heat Converting Agent)

The image recording layer for the image forming methods of the first to third aspects of the invention is required to be added a light-to-heat converting agent that absorbs light energy and converts it to heat. In this case, a light-to-heat converting agent may be added at least in the microcapsules and the recording layer matrix. In the invention, a light-to-heat converting agent is preferably added to the microcapsules in view of effective distribution of infrared radiation energy for image formation.

As the light-to-heat converting agent, a substance that absorbs infrared radiation, especially near-infrared radiation (having wavelength of 700 to 1200 nm), and various known pigments, dyes or colorants, and metal particles can be used therefor.

For example, pigments, dyes or colorants and metal particles disclosed in JP-A Nos. 2001-301350 and 2002-137562, Journal of Japanese Society of Printing Science and Technology, Vol. 38, pp. 35 to 40 (2001) “Novel Imaging Material, 2. Near-infrared radiation absorbing pigment” are preferably used. These pigments and metal particles can be used, if necessary, after provision of a known surface treatment.

More specifically, the dyes or pigments include cyanine colorants, polymethine colorants, azomethine colorants, squalelium colorants, pyrilium dyes and thiopyrilium salt dyes, dithiolmetal complexes, phthalocyanine colorants as disclosed in U.S. Patent Nos. 4756993 and 4973572, JP-A Nos. 10-268512 and 11-235883, JP-B Nos. 5-13514, 5-19702 and JP-A No. 2001-347765. More preferred are cyanine colorants, squalelium colorants, pyrilium salts and phthalocyanine colorants.

As the pigments, insoluble azo pigments, azo lake pigments, condensed azo pigments, chelate azo pigment, phthalocyanine pigments, anthraquinone pigments, perylene and perynone pigments, thioindigo pigments, quinacridone pigments, dioxazine pigments, isoindolinone pigments, quinophthalone pigments, dye lake pigments, azine pigments, nitroso pigments, nitro pigments, natural pigments, fluorescent pigments, inorganic pigments and carbon black can be used. Among these, carbon black is preferred.

As the metal particles, particles of Ag, Au, Cu, Sb, Ge and Pb can be preferred, particles of Ag, Au and Cu are more preferred.

Hereinafter the specifically preferred examples of a light-to-heat converting agent. However, the invention should not be construed to be limited to these examples. The (IR-1) to (IR-12) are hydrophilic light-to-heat converting agents preferable to be added to the image recording layer matrix, and the (IR-21) to (IR-30) are lipophilic light-to-heat converting agents preferable to be incorporated in the microcapsules.

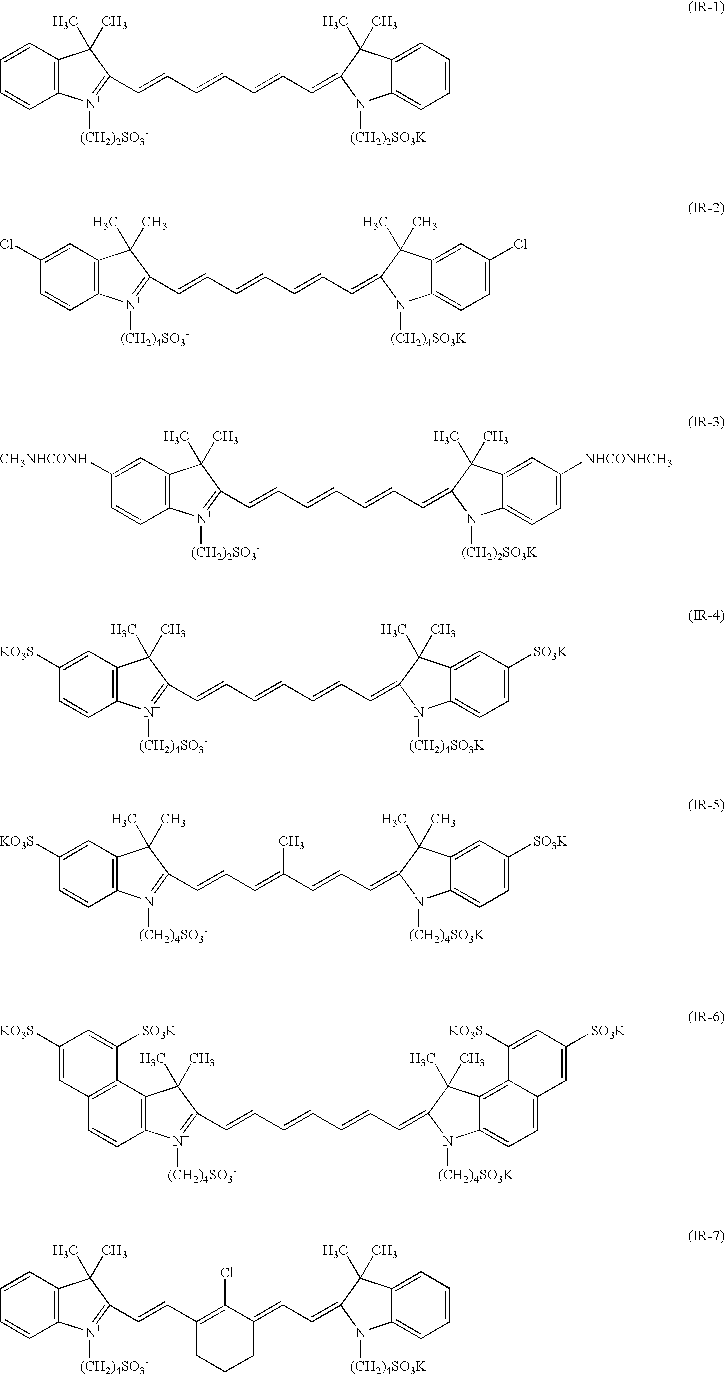

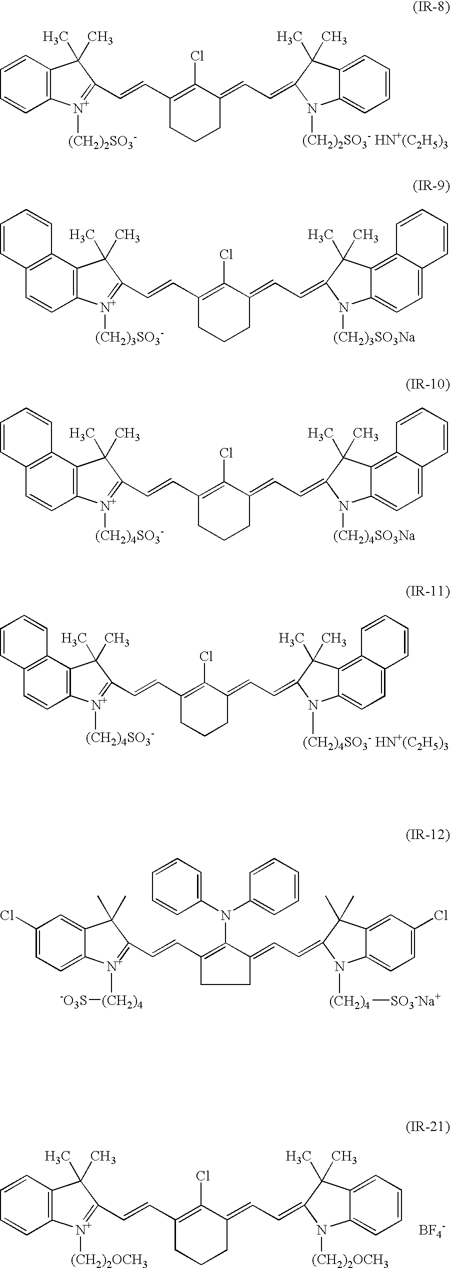

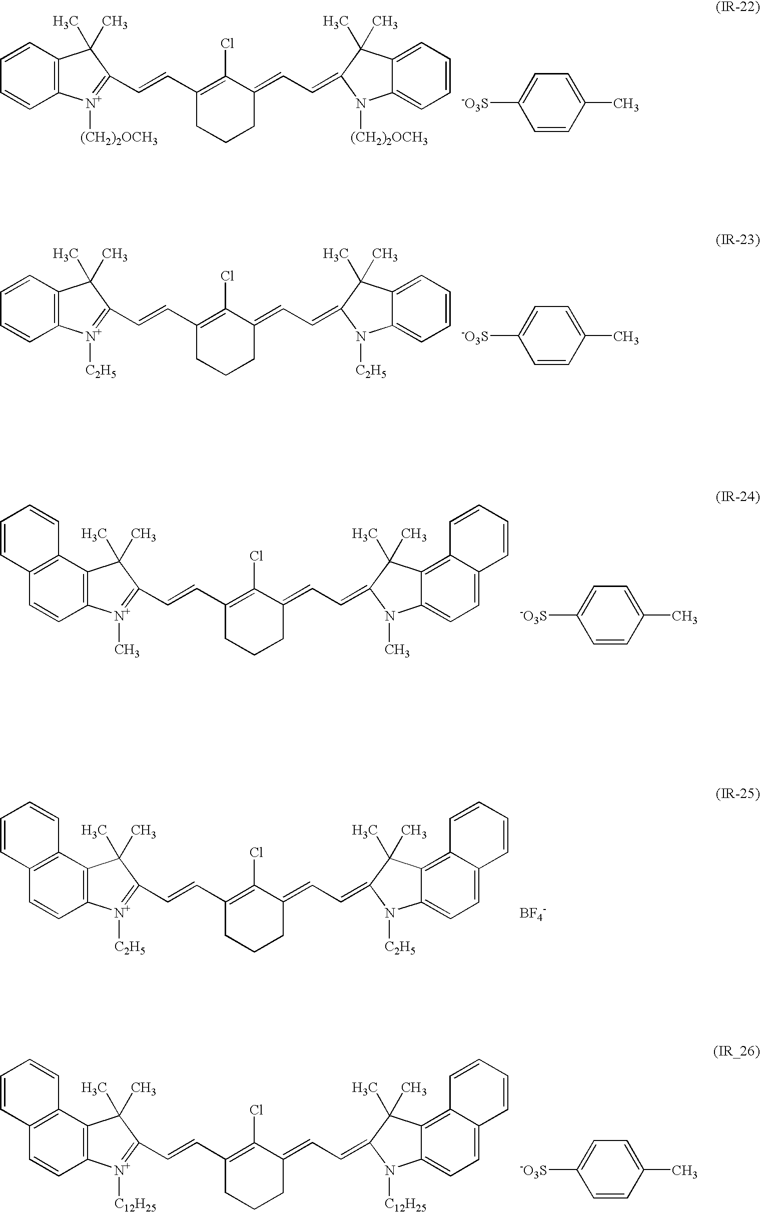

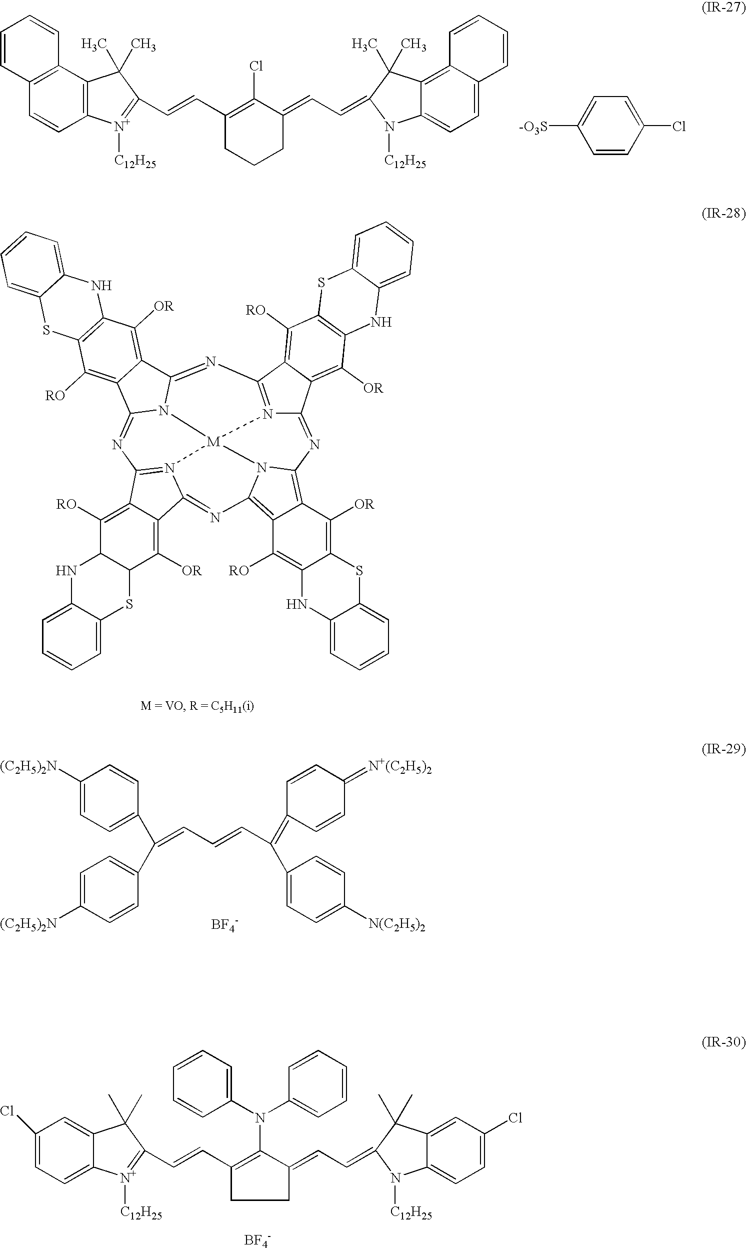

When the light-to-heat converting agent is added to the microcapsules, the amount to be added is preferably 1 to 50% by mass, and more preferably 3 to 25% by mass based on the whole microcapsule contents. On the other hand, when the light-to-heat converting agent is added to the image recording layer matrix, the amount to be added is preferably 1 to 50% by mass, and more preferably 3 to 25% by mass based on the solid portion of the recording layer solid. In this range, the film strength of the recording layer is not deteriorated, and good sensitivity can be obtained.

(Polymerization Initiator)

When the heat reactive compound is a polymerizable compound, a polymerization initiator is required to be added to the recording layer according to the first embodiment of the invention. A reaction initiator is generated from the polymerization initiator due to energy of image exposure, and initiates and accelerates the reaction of the polymerizable compound. In this case, although the polymerization initiator may be added to at least one of the microcapsules and the image recording layer matrix, it is preferably to add the initiator to the recording layer matrix so that it exists across the microcapsule wall from the polymerizable compound in view of stability.

The kind of the polymerization initiator used for the invention includes known acid generators and radical generators. The former is used in the case wherein a cationic polymerizable compound is used as a polymerizable compound in the microcapsules, and the latter is used in the case wherein a radical polymerizable compound is used as a polymerizable compound.

Alternatively, a printing-out system can be formed in combination with a generated acid or a dye that discolors by radical.

Hereinafter the polymerization initiators are explained.

<Acid Generator>

The acid generator used for the image forming methods according to the first to third aspects of the invention is not specifically limited so long as it absorbs heat and generates an acid. As such acid generator, known precursors and acid generators are preferably used, and examples include acid generators for printing-out image-forming, acid generators used for microresists.

More specifically, examples thereof can include organic halogen compounds such as trihalomethyl-substituted heterocyclic compounds disclosed in JP-A Nos. 2002-29162, 2002-46361, 2002-137562, compounds generating sulfonic acid by photodecomposition such as iminosulfonates, disulfone compounds or onium salts (for example, iodonium salt, diazonium salt and sulfonium salt). Alternatively, a compound in which the group or compound that generates an acid has been introduced in the main chain or side chain of a polymer can be used.

Hereinafter the specific embodiments thereof are exemplified. However, the invention should not be construed to be limited thereto.

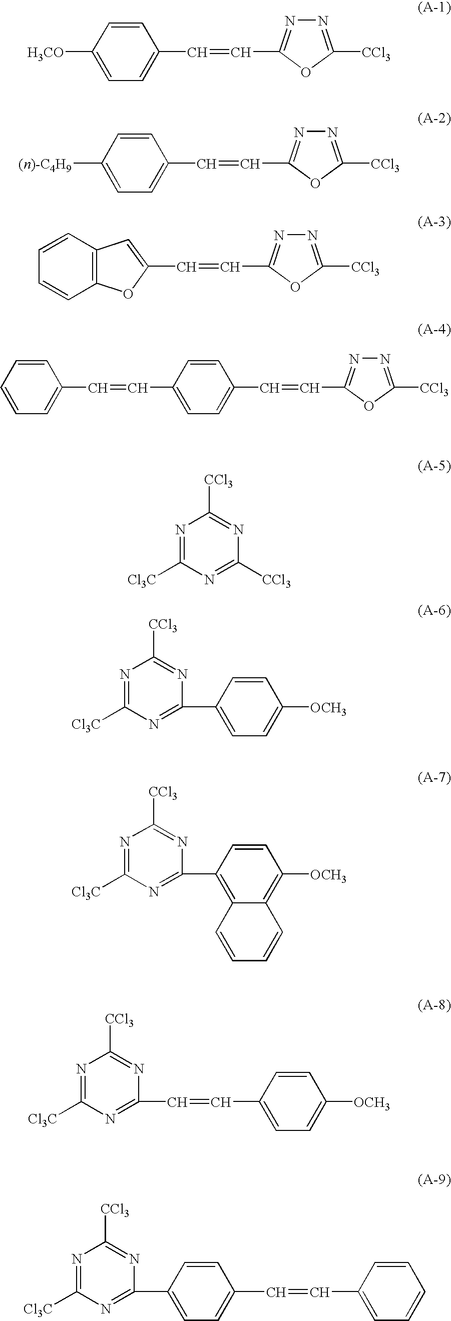

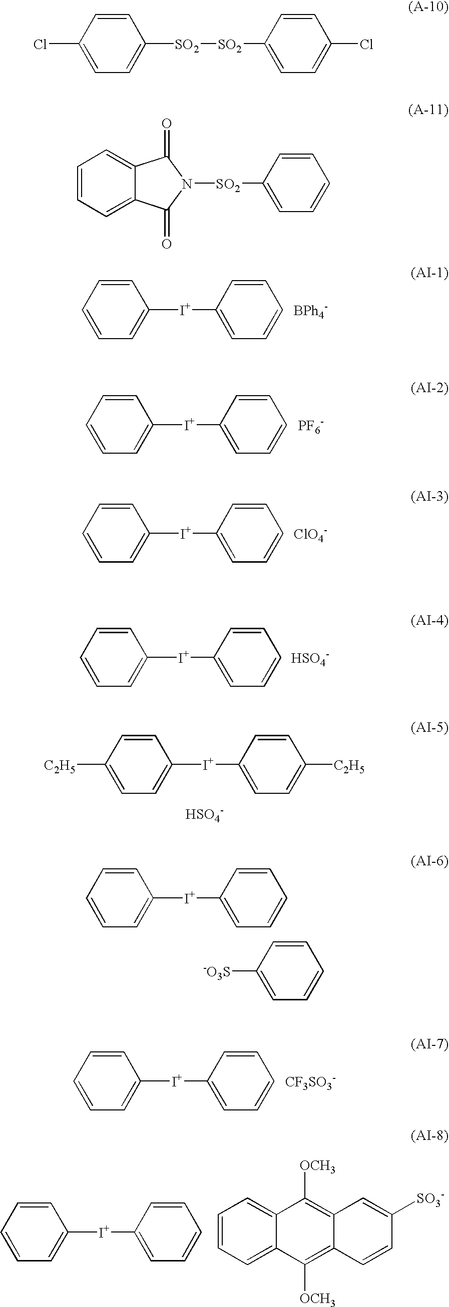

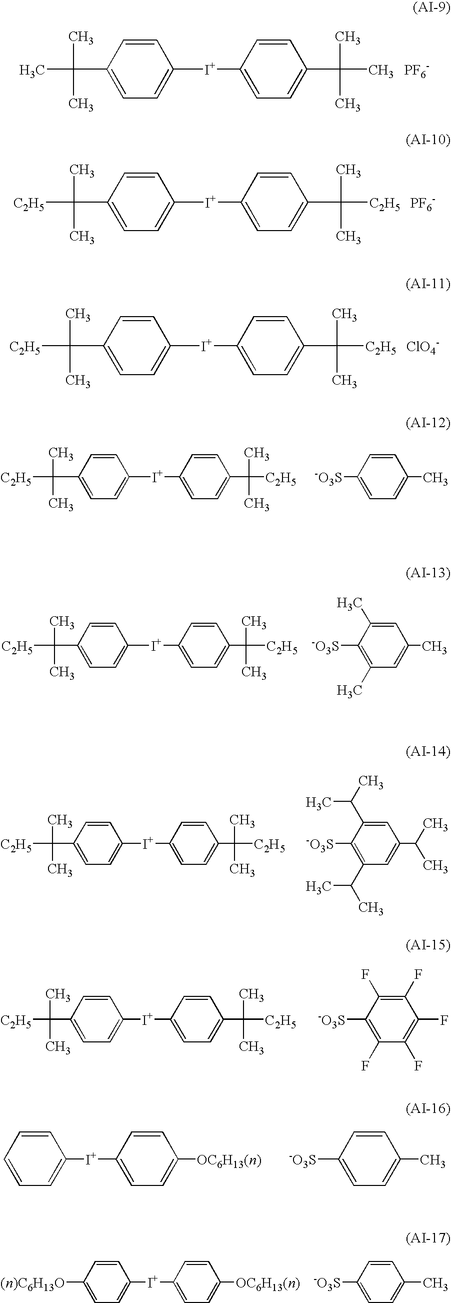

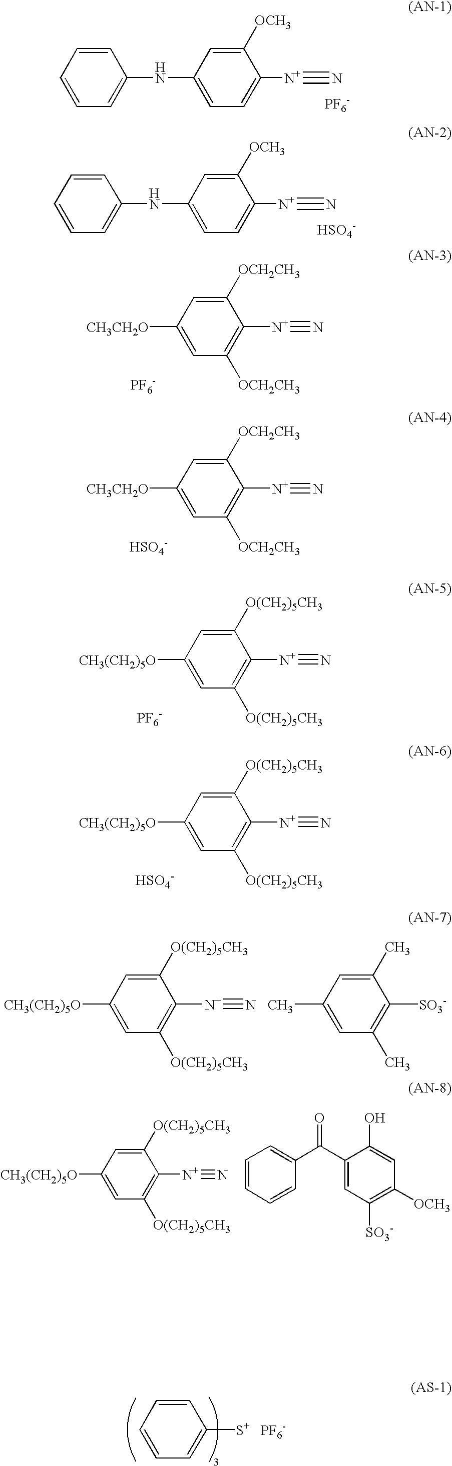

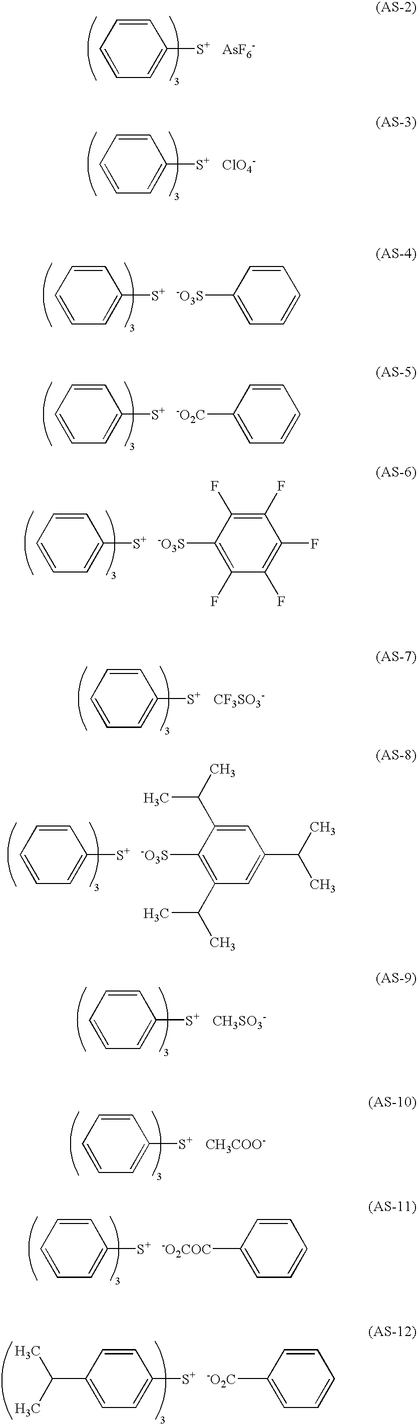

The above-mentioned acid generators can also be used in combination of two kinds or more.

The amount to be added of the acid generator is preferably 0.01 to 20% by mass, and more preferably 0.1 to 10% by mass based on the whole solid portion of the recording layer. In this range, good effects on initiation or acceleration of the reaction can be obtained without deteriorating property for developing-on-press.

<Radical Generator>

The radical generator used for the image forming methods according to the first to third aspects of the invention is not specifically limited so long as it absorbs heat and generates radical. As such radical generator, known heat radical generators are preferably used, and examples thereof include photoinitiators for photo radical polymerization and the like.

Specifically, compounds generating sulfonic acid, disulfone compounds or onium salts (for example, iodonium salt, diazonium salt and sulfonium salt), which are exemplified as the acid generators above, can also be used as a radical generator. Specific examples can include, but are not limited to, the above-mentioned compounds (AI-1) to (AI-17), (AN-1) to (AN-8) and (AS-1) to (AS-12).

The above-mentioned radical generators can also be used in combination of two kinds or more.

The amount to be added of the radical generators is preferably 0.01 to 20% by mass, and more preferably 0.1 to 10% by mass based on the whole solid portion of the recording layer. In this range, good effects on initiation or acceleration of the reaction can be obtained without deteriorating property for developing-on-press.

In the image forming method according to the first aspect of the invention, the microcapsule wall material becomes permeable by initiation and acceleration of decomposition of the polymerization initiator (an acid generator or a radical generator) by the post-heating in the post-heating process, which provides the effect of improving the efficiency of the curing agent between the polymerizable compound released in the reaction system and the polymerization initiator. Accordingly, the post-heating temperature is preferably higher than the temperature on which the decomposition of the polymerization initiator is initiated and accelerated, and more preferably higher by at least 10° C. than the decomposition temperature. The decomposition temperature for the polymerization initiator differs depending on the kind of the compound, for example, the temperature is about 160° C. for diphenyliodoniumtrifluoromethanesulfonic acid (AI-7; the acid generator exemplified in the present specification), and is about 200° C. for triphenylsulfoniumbenzoylformic acid (AS-11; the radical generator exemplified in the present specification).

In the case wherein the image forming method according to the second aspect of the invention is applied to the planographic printing plate precursor according to the first embodiment, the microcapsule wall material becomes permeable by initiation and acceleration of decomposition of the polymerization initiator (an acid generator or a radical generator) by the spot-heating in the post-heating process, which provides the effect of improving the efficiency of the curing agent between the polymerizable compound released in the reaction system and the polymerization initiator. Accordingly, the post-heating temperature is preferably higher than the temperature on which the decomposition of the polymerization initiator is initiated and accelerated, and more preferably higher by at least 10° C. than the decomposition temperature. The decomposition temperature for the polymerization initiator differs depending on the kind of the compound, for example, the temperature is about 160° C. for diphenyliodoniumtrifluoromethanesulfonic acid (AI-7; the acid generator exemplified in the present specification), and is about 200° C. for triphenylsulfoniumbenzoylformic acid (AS-11; the radical generator exemplified in the present specification).

In the image forming method according to the third aspect of the invention, the microcapsule wall material becomes permeable by acceleration of decomposition of the polymerization initiator (an acid generator or a radical generator) by the heating carried out concurrently with image exposure in the heating process, which provides the effect of improving the efficiency of the curing agent between the polymerizable compound released in the reaction system and the polymerization initiator. Accordingly, the post-heating temperature is preferably higher than the temperature on which the decomposition of the polymerization initiator is initiated and accelerated, and more preferably higher by at least 10° C. than the decomposition temperature. The decomposition temperature for the polymerization initiator differs depending on the kind of the compound, for example, the temperature is about 160° C. for diphenyliodoniumtrifluoromethanesulfonic acid (AI-7; the acid generator exemplified in the present specification), and is about 200° C. for triphenylsulfoniumbenzoylformic acid (AS-11; the radical generator exemplified in the present specification).

In the image forming methods of the first to third aspects of the invention, a compound that decolors by an acid or radical can be added to form a printing-out image. As such compound, various colorants such as diphenylmethane colorants, triphenylmethane colorants, thiazine colorants, oxazine colorants, xanthene colorants, anthraquinone colorants, iminoquinone colorants, azo colorants and azomethine colorants can be used effectively.

Specific examples include dyes such as brilliant green, ethyl violet, methyl green, crystal violet, basic fuchsine, methyl violet 2B, quinaldine red, rose bengal, methanyl yellow, thymolsulfophthalein xylenol blue, methyl orange, paramethyl red, congo red, benzopurpurin 4B, α-naphthyl red, nile blue 2B, nile blue A, methyl violet, maracaibo green, parafuchsine, victoria pure blue BOH [manufactured by Hodogaya Chemical Co., Ltd.], oil blue #603[manufactured by Orient Chemical Co., Ltd.], oil pink #312 [manufactured by Orient Chemical Co., Ltd.], oil red 5B [manufactured by Orient Chemical Co., Ltd.], oil scarlet #308 [manufactured by Orient Chemical Co., Ltd.], oil red OG [manufactured by Orient Chemical Co., Ltd.], oil red RR [manufactured by Orient Chemical Co., Ltd.], oil green #502 [manufactured by Orient Chemical Co., Ltd.], spironred BEH special [manufactured by Hodogaya Chemical Co., Ltd.], m-cresol purple, cresol red, rhodamine B, rhodamine 6G, sulforhodamine B, auramine, 4-p-diethylaminophenyliminonaphthoquinone, 2-carboxyanilino-4-p-diethylaminophenyliminonaphthoquinone, 2-carboxystearylamino-4-p-N,N-bis(hydroxyethyl)aminophenyliminonaphthoquinone, 1-phenyl-3-methyl-4-p-diethylaminophenylimino-5-pyrazolone and 1-β-naphthyl-4-p-diethylaminophenylimino-5-pyrazolone, leuco dyes such as p,p′,p″-hexamethyltriaminotriphenylmethane (leuco crystal violet) and Pergascript Blue SRB (manufactured by Ciba Geigy).

In addition to the above-mentioned dyes, leuco dyes, which are known as a material for thermosensitive paper and pressure sensitive paper, are also exemplified as preferred examples. Specific examples include crystalviolet lactone, maracaibo green lactone, benzoyl leuco methylene blue, 2-(N-phenyl-N-methylamino)-6-(N-p-tolyl-N-ethyl)aminofluorane, 2-anilino-3-methyl-6-(N-ethyl-p-toluidino)fluorane, 3,6-dimethoxyfluorane, 3-(N,N-diethylamino)-5-methyl7-(N,N-dibenzylamino)fluorane, 3-(N-cyclohexyl-N-methylamino)-6-methyl-7-anilinofluorane, 3-(N,N-diethylamino)-6-methyl-7-anilinofluorane, 3-(N,N-diethylamino)-6-methyl-7-xylidinofluorane, 3-(N,N-diethylamino)-6-methyl-7-chlorofluorane, 3-(N,N-diethylamino)-6-methoxy-7-aminofluorane, 3-(N,N-diethylamino)-7-(4-chloroanilino)fluorane, 3-(N,N-diethylamino)-7-chlorofluorane, 3-(N,N-diethylamino)-7-benzylaminofluorane, 3-(N,N-diethylamino)-7,8-benzofluorane, 3-(N,N-dibutylamino)-6-methyl-7-anilinofluorane, 3-(N,N-dibutylamino)-6-methyl-7-xylidinofluorane, 3-piperidino-6-methyl-7-anilinofluorane, 3-pyrrolidino-6-methyl-7-anilinofluorane, 3,3-bis(1-ethyl-2-methylindol-3-yl)phthalide, 3,3-bis(1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-azaphthalide and 3-(4-diethylaminophenyl)-3-(1-ethyl-2-methylindol-3-yl)phthalide.

The amount to be added of the dye that decolors by an acid or radical is preferably 0.01 to 10% by mass based on the solid portion in the recording layer.

(Hydrophilic Resin)

A hydrophilic resin may be added to the first embodiment of the image recording layer matrix that can be applied to the image forming methods according to the first to third aspects of the invention so as to improve property for developing-on-press and the film strength of the recording layer.

The hydrophilic resin having hydrophilic group such as hydroxyl group, amino group, carboxyl group, phosphoric acid group, sulfonic acid group or amide group is preferred. Furthermore, the hydrophilic resin preferably has a functional group that reacts with the reactive group included in the microcapsules (a cationic polymerizable group, an ethylenically unsaturated group, a heat reactive group) or a reactive group of the polymer particles, since these group improves image strength and printing durability by crosslinking. For example, when the cationic polymerizable compound has vinyloxy group or epoxy group, the hydrophilic resin is preferably a resin having hydroxyl group, carboxyl group, phosphoric acid group or sulfonic acid group. Among these, a hydrophilic resin having hydroxyl group or carboxyl group is preferred.

Specific examples of the hydrophilic resin include gum arabic, casein, gelatin, starch derivative, soy gum, hydroxypropylcellulose, methylcellulose, carboxymethylcellulose and a sodium salt thereof, cellulose acetate, sodium alginate, vinyl acetate-maleic acid copolymers, styrene-maleic acid copolymers, polyacrylic acids and a salt thereof, polymethacrylic acids and a salt thereof, homopolymer and copolymer of hydroxyethylmethacrylate, homopolymer and copolymer of hydroxyethylacrylate, homopolymer and copolymer of hydroxypropylmethacrylate, homopolymer and copolymer of hydroxypropylacrylate, homopolymer and copolymer of hydroxybutylmethacrylate, homopolymer and copolymer of hydroxybutylacrylate, polyethyleneglycols, hydroxypropylene polymers, polyvinylalcohols, hydrolyzed polyvinylacetate having hydrolysis degree of at least 60% by mass, preferably at least 80% by mass, polyvinylformal, polyvinylpyrrolidone, homopolymer and copolymer of acrylamide, homopolymer and copolymer of methacrylamide, homopolymer and copolymer of N-methylolacrylamide, homopolymer and copolymer of 2-acrylamide-2-methyl-1-propanesulfonic acid, homopolymer and copolymer of 2-methacryloyloxyethylphosphonic acid.

The amount to be added of the hydrophilic resin is not more than 20% by mass, preferably not more than 10% by mass based on the whole solid portion of the recording layer.

The above-mentioned hydrophilic resin can be crosslinked to the extent that the unexposed portion can be subjected to developing-on-press on the printer and used. The crosslinking agent to be used for crosslinking the hydrophilic resin includes aldehydes such as glyoxal, melamineformaldehyde resin and urea formaldehyde resin, methylol compounds such as N-methylolurea, N-methylolmelamine and methylolated polyamide resin, active vinyl compounds such as divinylsulfone and bis(p-hydroxyethylsulfonic acid), epoxy compounds such as epichlorohydrin, polyethyleneglycol diglycidylether, polyamide, polyamine, epichlorohydrin adduct and polyamide epichlorohydrin resin, ester compounds such as monochloroacetic acid ester and thioglycolic acid ester, polycarboxylic acids such as polyacrylic acid and methylvinylether/maleic acid copolymer, inorganic crosslinking agents such as boric acid, titanyl sulfate and Cu, Ai, Sn, V, Cr salts, and modified polyamide polyimide resin. In addition, crosslinking catalysts such as ammonium chloride, a silane coupling agent and a titanate coupling agent can be used in combination.

(Other Additives)

In the image forming methods according to the first to third aspects of the invention, various compounds other than those described above can be added, if necessary, to the recording layer matrix of the first embodiment.

<Multifunctional Monomer>

A multifunctional monomer can be added to the recording layer matrix of the first embodiment used for the image forming methods of the first to third aspects of the invention so as to further improve printing durability. As the multifunctional monomer, those exemplified as the monomers to be included in the microcapsules can be used. Among these, preferable monomers can include trimethylolpropane triacrylate and pentaerithritol triacrylate. The amount to be added of the multifunctional monomer is preferably 0.1 to 50% by mass, and more preferably 0.5 to 30% by mass in the whole solid component of the recording layer.

<Heat Polymerization Preventing Agent>

It is desirable to add a small amount of heat polymerization preventing agent to the recording layer matrix of the first embodiment for the image forming methods according to the first to third aspects of the invention during preparation or storage of the recording layer coating solution so as to prevent unnecessary heat polymerization of the ethylenically unsaturated compound. Suitable heat polymerization preventing agent includes hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol) and N-nitroso-N-phenylhydroxylamine aluminum salt. The amount to be added of the heat polymerization preventing agent is preferably 0.01 to 5% by mass of the whole solid portion of the recording layer.

<Higher Aliphatic Acid or a Derivative Thereof>

If necessary, a higher aliphatic acid such as behenic acid, behenic acid amide or a derivative thereof can be added to the recording layer matrix of the first embodiment for the image forming method of the first to third aspects of the invention to distribute the acid unevenly on the surface of the recording layer during drying of the layer after application, so as to prevent inhibition of polymerization by oxygen. The amount to be added of the higher aliphatic acid or a derivative thereof is preferably 0.1 to 10 % by mass based on the whole solid layer of the recording layer.

<Inorganic Particles>

Inorganic particles can be added to the recording layer matrix of the first embodiment for the image forming methods according to the first to third aspects of the invention, and preferred examples of the inorganic particles include silica, alumina, magnesium oxide, titanium oxide, magnesium carbonate, calcium alginate or a mixture thereof. These can be used for strengthening of the film and strengthening of interface adhesiveness by surface roughening, even if they do not have light-to-heat converting property.

The average particle size of the inorganic particles is preferably 5 nm to 10 μm, and more preferably 10 nm to 1 μm. When the particle size is in this range, the microcapsules and the metal particles of the light-to-heat converting agent disperse stably in the hydrophilic resin, and can provide a non-image portion having superior hydrophilicity, which retains film strength of the recording layer sufficiently and being difficult to generate printing contamination.

Such inorganic particles can be readily avairable as a commercial product such as a colloidal silica dispersion. The amount to be added of the inorganic particles in the recording layer is preferably not more than 20% by mass, and more preferably not more than 10% by mass based on the whole solid portion of the recording layer.

<Surfactant>

A nonionic, anionic, cationic, amphoteric or fluorine surfactant disclosed in JP-A Nos. 2-195356, 59-121044 and 4-13149 and 2002-365789 can be added to the recording layer matrix of the first embodiment for the image forming methods of the first to third aspects of the invention so as to improve dispersing stability of the recording layer, plate-making property and printing property, and to improve coating property. The preferred amount to be added of the surfactant is 0.005 to 1% by mass based on the whole solid portion of the recording layer.

<Plasticizer>

If necessary, a plasticizer can be added to the recording layer matrix of the first embodiment for the image forming methods of the first to third aspects of the invention so as to provide flexibility of the film. For example, polyethyleneglycol, tributyl citrate, tributyl phthalate, dibutyl phthalate, dihexyl phthalate, dioctyl phthalate, tricresyl phosphate, tributyl phosphate, trioctyl phosphate and tetrahydrofurfuryl oleate are used.

[Image Recording Layer Including (b) Thermoplastic Polymer Particles and a Light-to-Heat Converting Agent]

The image recording layer of the second embodiment of the invention is characterized in including a thermoplastic polymer particles and a light-to-heat converting agent.

((b) Thermoplastic Polymer Particles)

The thermoplastic polymer particles used in the second embodiment are not specifically limited so long as they can form a surface hydrophobic portion, i.e., an image portion.

Preferred thermoplastic polymer particles used for the invention include thermoplastic polymer particles disclosed in Research Disclosure No. 33303 issued on January, 1992, JP-A Nos. 9-123387, 9-131850, 9-171249 and 9-171250 and EP No. 931647.

Specific examples of the polymer constituting such thermoplastic polymer particles can include homopolymers or copolymers of ethylene, styrene, vinyl chloride, methyl acrylate, ethyl acrylate, methyl methacrylate, ethyl methacrylate, vinylidene chloride, acrylonitrile, vinylcarbazole or the like, or mixtures thereof. Among these, more preferred examples can include polystyrene and polymethyl methacrylate.

The average particle size of the thermoplastic polymer particles used for the invention is preferably 0.01 to 2.0 μm. Since they are extremely fine particles as mentioned, they form a strong image portion area by fusion and coalescence each other by slight thermal energy to form a hydrophobic portion, and by cool-curing together with the completion the provision of thermal energy.

The synthesis method of such thermoplastic polymer particles includes emulsification polymerization method, suspension polymerization method, and a method including dissolving these compounds in a water insoluble organic solvent, mixing and emulsifying the mixture to form an aqueous solution including a dispersing agent, and further heating the solution to evaporate the organic solvent to solidify particles (solution dispersion method).

The softening temperature of these thermoplastic polymer particles is preferably not less than 35° C., and more preferably not less than 70° C. in view of stability for a long time. Furthermore, when such thermoplastic polymer particles are applied to the recording layer of the invention, the post-heating temperature is preferably lower by at least 10° C. than the softening temperature so as to suppress fusion of the particles in the undesired area.

The amount to be added of the (b) thermoplastic polymer particles as a hydrophobic precursor to the recording layer is preferably not less than 50% by mass, and more preferably not less than 60% by mass based on the whole solid portion of the image recording layer. Although the amount to be added may be 100% by mass, it is preferably not more than 90% by mass in view of stability of particles.

(Light-to-Heat Converting Agent)

It is necessary to add a light-to-heat converting agent that absorbs photo energy and converts it to heat to the recording layer according to the second embodiment. As the light-to-heat converting agent used herein, the light-to-heat converting agents as exemplified for the recording layer of the first embodiment can be used, and the amount to be added is preferably in the same range as recited in the first embodiment.

(Hydrophilic Resin)

A hydrophilic resin can be added to the recording layer according the second embodiment of the invention so as to improve property for developing-on-press and film strength of the recording layer. As the hydrophilic resin used herein, the hydrophilic resins as exemplified for the recording layer of the first embodiment can be used, and the amount to be added is preferably in the same range for the recording layer of the first embodiment.

(Other Additives)

Multifunctional monomers, higher aliphatic acids or derivatives thereof, inorganic particles, surfactants and plasticizers can be added, if necessary, to the recording layer according the second embodiment of the invention. As the components used herein, the additives as exemplified for the recording layer of the first embodiment can be used, and the amount to be added is preferably in the same range as recited in the first embodiment.

[Image Recording Layer Including (c) Polymer Particles Including Heat Reactive Group and a Light-to-Heat Converting Agent]

The image recording layer according to the third embodiment of the invention includes polymer particles including a heat reactive group and a light-to-heat converting agent. When the heat reactive group is a polymerizable group, it is preferable for the image recording layer to include a polymerization initiator that generates a reaction initiator (active species) due to energy of image exposure.

((c) Polymer Particles Including a Heat Reactive Group)

The polymer particles including a heat reactive group, which is used as a hydrophobic precursor used for the third embodiment of the image forming methods according to the first to third aspects of the invention can be divided into heat-curable polymer particles, which have heat-crosslinkable functional group in a polymer and form crosslinking structure each other and cure by heating to exhibit a property that they do not melt again, and polymer particles having so-called heat reactive functional group, which can react by heat to form an interaction between the adjacent particles to form a hydrophobic portion.

<Heat-Curable Polymer Particles>

The heat-curable polymer can include resins having phenol skeleton, urea resins (for example, a resin obtained by resin-formation of a urea derivative such as urea or methoxymethylated urea with an aldehyde such as formaldehyde), melamine resins (for example, a resin obtained by resin-formation of melamine or a derivative thereof with an aldehyde such as formaldehyde), alkyd resins, unsaturated polyester resins, polyurethane resins, epoxy resins. Among these, resins having phenol skeleton, melamine resins, urea resins and epoxy resins are specifically preferred.

Examples of preferred resins having phenol skeleton include, for example, phenol resins formed by resin-formation of phenol or cresol with an aldehyde such as formaldehyde, hydroxystyrene resin, and polymers or copolymers of methacrylamide or acrylamide or methacrylate or acrylate each having phenol skeleton, such as N-(p-hydroxyphenyl)methacrylamide and p-hydroxyphenylmethacrylate.

The average particle size used for the heat-curable polymer particles of the invention is preferably 0.01 to 2.0 μm.

The curing temperature for these heat-curable polymer particles is preferably not less than 70° C., and more preferably not less than 100° C.

Such heat-curable polymer particles can be readily available by a known solution dispersion method, or alternatively, can be obtained by forming particles during the synthesis of the heat-curable polymer. However, the invention is not limited to these methods.

<Polymer Particles Including Heat Reactive Functional Group>

The heat reactive functional group used for the polymer particles having heat reactive functional group used for the image forming methods according to the first to third aspects of the invention may be any reactive functional group so long as it forms chemical bond by heat. Preferred examples include ethylenically unsaturated group for radical polymerization reaction (for example, acryloyl group, methacryloyl group, vinyl group and allyl group); cationic polymerizable group (for example, vinyl group, vinyloxy group and epoxy group); isocyanate group or a block form thereof; epoxy group and vinyloxy group for addition reaction, and functional group having active hydrogen atom, which is a reaction partner therefor (for example, amino group, hydroxyl group and carboxyl group); carboxyl group for condensation reaction and hydroxyl group or amino group, which is a reaction partner therefor; acid anhydride for ring-opening addition reaction and amino group or hydroxyl group, which is a reaction partner therefor.

The heat reactive functional group can be introduced in polymer particles during polymerization, or can be introduced by using polymer reaction after polymerization.

In the case of introduction during polymerization, emulsification polymerization or suspension polymerization of the monomer having heat reactive functional group is preferable.

Specific examples of the monomers having heat reactive functional group include, but are not limited to, allyl methacrylate, allyl acrylate, vinyl methacrylate, vinyl acrylate, 2-(vinyloxy)ethyl methacrylate, p-vinyloxystyrene, p-{2-(vinyloxy)ethyl}styrene, glycidyl methacrylate, glycidyl acrylate, block isocyanate of 2-isocyanateethyl methacrylate or an alcohol thereof or the like, block isocyanate of 2-isocyanateethyl acrylate or an alcohol thereof or the like, 2-aminoethyl methacrylate, 2-aminoethyl acrylate, 2-hydroxyethyl methacrylate, 2-hydroxyethyl acrylate, acrylic acid, methacrylic acid, maleic anhydride, difunctional acrylate and difunctional methacrylate.

Alternatively, in the invention, a copolymer of the above monomer and a monomer having no heat reactive functional group that can be polymerized with the monomer can be used. The copolymerizable monomer having no heat reactive functional group can include, for example, styrene, alkylacrylate, alkylmethacrylate, acrylonitrile, vinyl acetate and like, but is not limited to these so long as it has no heat reactive functional group.

The polymer compound reaction used for the introduction of the heat reactive functional group after the polymerization of the polymer includes, for example, polymer compound reaction disclosed in WO96-34316.

Among the polymer particles having heat reactive functional group, polymer particles easily fused and coalesced by heat are preferable in view of image-forming property. Specifically, the surface of the particles is preferably hydrophilic and capable of dispersing in water in view of property for developing-on-press.

Furthermore, the contact angle of the film (water droplets in air) prepared by applying only polymer particles having heat reactive functional group and drying at a temperature being lower than the solidification temperature is preferably lower than the contact angle (water droplets in air) of the film prepared by drying at the temperature being higher than the solidification temperature. The hydrophilicity of the surface of the polymer particles can be adjusted to such preferably state by adsorbing a hydrophilic polymer such as polyvinylalcohol or polyethyleneglycol, or an oligomer or a hydrophilic low molecular compound to the surface of polymer particles. However, the method for hydrophilizing the surface of particles is not limited to this method, and various known methods for hydrophilizing the surface of particles can be applied.

The average particle size of the polymer particles having heat reactive functional group used for the invention is preferably 0.01 to 2.0 μm, more preferably 0.05 to 2.0 μm, and most preferably 0.1 to 1.0 μm. In this range, good resolution and stability for a long time can be obtained.

The melting point of polymer particles having heat reactive functional group is preferably not less than 70° C., and more preferably not less than 100° C. in view of stability for a long time. When such polymer particles having heat reactive functional group are applied to the recording layer the according to the invention, the post-heating temperature is preferably greater by at least 10° C. than the glass transition temperature of the polymer particles, and preferably lower by at least 10° C. than the melting point of the polymer particles. Since the temperature is greater than the glass transition temperature, the movability of the reactive group is improved and the crosslinking reaction is accelerated. For example, the glass transition temperature of a copolymer of styrene and glycidyl methacrylate is about 60° C., whereas preferable post-heating temperature is about 80° C.

The amount to be added of the (c) polymer particles including a heat reactive group as a hydrophobic precursor to the recording layer is preferably not less than 50% by mass, and more preferably not less than 60% by mass based on the whole solid portion of the image recording layer. Although the amount to be added may be 100% by mass, it is preferably not more than 90% by mass in view of stability of particles.

(Light-to-Heat Converting Agent)

It is necessary to add a light-to-heat converting agent that absorbs photo energy and converts it to heat to the recording layer according to the third embodiment. Examples of the light-to-heat converting agent used here include the light-to-heat converting agents recited as the light-to-heat converting agents of the first embodiment. The amount to be added is preferably in the same range as recited in the first embodiment.

(Polymerization Initiator)

When the heat reactive group included in the polymer particles is a polymerizable group, a polymerization initiator is preferably added to the recording layer according to the third embodiment. A reaction initiator is generated from the polymerization initiator due to energy of image exposure, and initiates and accelerates the reaction of the polymerizable compound. Examples of the polymerization initiator that can be used here include the polymerization initiators recited as the polymerization initiators of the first embodiment. The amount to be added is preferably in the same range as recited in the first embodiment.

(Hydrophilic Resin)

A hydrophilic resin can be added to the recording layer according the third embodiment of the invention so as to improve property for developing-on-press and film strength of the recording layer. As the hydrophilic resin used herein, the hydrophilic resins as exemplified for the recording layer of the first embodiment can be used, and the amount to be added is preferably in the same range for the recording layer of the first embodiment.

(Other Additives)

Multifunctional monomers, higher aliphatic acids or derivatives thereof, inorganic particles, surfactants and plasticizers can be added, if necessary, to the recording layer according the third embodiment of the invention. As the components used herein, the additives as exemplified for the recording layer of the first embodiment can be used, and the amount to be added is preferably in the same range as recited in the first embodiment.

-Image Recording Layer Including Polymerizable Compound, Polymerization Initiator and Light-to-Heat Converting Agent-

An image recording layer including a polymerizable compound, a polymerization initiator and a light-to-heat converting agent is characterized in that the polymerizable compound causes a polymerization reaction due to energy of image exposure, whereby forming a hydrophobic image portion. Examples of the polymerizable compound used herein include the cationic polymerizable compound and radical polymerizable compound, which are recited in the first embodiment, or (d) microcapsules containing any of these polymerizable compounds. Alternatively, the examples of the polymerizable compound include (e) polymer particles including a polymerizable group recited as the heat reactive group included in polymer particles in the third embodiment. Among them, it is preferable to use (d) microcapsules containing a polymerizable compound or (e) polymer particles including a polymerizable group.

An image recording layer including a polymerizable compound, a polymerization initiator and a light-to-heat converting agent is not necessarily hydrophilic. For instance, it may be a hydrophobic layer including a hydrophobic resin, which will be described below, for the purpose of improve the film strength of the image portion.

Preferable embodiments (fourth and fifth embodiments) of the image recording layer including a polymerizable compound, a polymerization initiator and a light-to-heat converting agent will be described hereinafter.

[Image Recording Layer Including (d) Microcapsules Containing Polymerizable Compound, Polymerization Initiator and Light-to-Heat Converting Agent]

The fourth embodiment of the image recording layer is characterized in including microcapsules containing a polymerizable compound, a polymerization initiator and a light-to-heat converting agent.

((d) Microcapsules Containing Polymerizable Compound)

Examples of microcapsules containing a polymerizable compound that can be used in the fourth embodiment include microcapsules containing the cationic polymerizable compound and the radical polymerizable compound recited in the first embodiment. The description of the first embodiment may also apply to the method for microcapsulizing the polymerizable compound, wall materials of microcapsules, average particle size of microcapsules, temperature at which capsule wall material collapses or becomes permeable, etc.

The amount of microcapsules containing a polymerizable compound contained in the image recording layer of the fourth embodiment is preferably 10 to 90% by mass, and more preferably 30 to 60% by mass based on the whole solid content of the image recording layer, in view of image forming properties and printing durability.

(Polymerization Initiator)

A polymerization initiator is necessarily added to the image recording layer according to the fourth embodiment. A reaction initiator is generated from the polymerization initiator due to energy of image exposure, and initiates and accelerates the reaction of the polymerizable compound. Examples of the polymerization initiator that can be used here include the polymerization initiators recited as the polymerization initiators of the first embodiment. The polymerization initiator may be included in at least one of inside of microcapsules and outside of microcapsules (in the recording layer matrix). The amount to be added is preferably in the same range as recited in the first embodiment.

(Light-to-Heat Converting Agent)

A light-to-heat converting agent that absorbs photo energy and converts it to heat may be added to the recording layer according to the fourth embodiment. As the light-to-heat converting agent used herein, the light-to-heat converting agents as exemplified for the recording layer of the first embodiment can be used. The light-to-heat converting agent may be added to at least one of inside the microcapsules and outside the microcapsules (in the image recording layer matrix). The amount to be added is preferably in the same range as recited in the first embodiment.

(Hydrophobic Resin)

A hydrophobic resin may be added to the image recording layer matrix of the fourth embodiment in order to improve the film strength of the image portion. Conventionally known hydrophobic resins may be used without particular limitation, and a linear organic polymer having film forming property can be preferably used. Examples of such a polymer include acrylic resins, polyvinyl acetal resins, polyurethane resins, polyurea resins, polyimide resins, polyamide resins, epoxy resins, methacrylic resins, polystyrene resins, novolak-type phenol resins, polyester resins, synthetic rubbers, and natural rubbers.

For further improvement of the film strength of the image portion, the hydrophobic resin preferably has a heat reactive group. For instance, a polymer in which an ethylenically unsaturated bond has been introduced in the main chain or in the side chain of the polymer can be used. Examples of the polymer including an ethylenically unsaturated bond in the main chain of the molecule include poly-1,4-butadiene and poly-1,4-isoprene. Examples of the polymer including an ethylenically unsaturated bond in the side chain of the molecule include a polymer of an ester or an amide of acrylic acid or mathacrylic acid, in which the residue of the ester or amide (i.e., R of —COOR or —CONHR) has an ethylenically unsaturated bond.

The amount of the hydrophobic resin contained in the image recording layer is preferably 5 to 50% by mass, and more preferably 10 to 30% by mass based on the whole solid content of the image recording layer, in view of compatibility of removability of the non-image portion and film strength of the image portion.

(Other Additives)

Hydrophilic resin, multifunctional monomers, higher aliphatic acids or derivatives thereof, inorganic particles, surfactants and plasticizers can be added, if necessary, to the recording layer according the fourth embodiment of the image recording layer-matrix. As the components used herein, the additives as exemplified for the recording layer of the first embodiment can be used, and the amount to be added is preferably in the same range as recited in the first embodiment.

[Image Recording Layer Including (e) Polymer Particles Including a Polymerizable Group, Polymerization Initiator and Light-to-Heat Converting Agent]

The fifth embodiment of the image recording layer is characterized in including polymer particles including a polymerizable group, a polymerization initiator and a light-to-heat converting agent.

((e) Polymer Particles Including a Polymerizable Group)

As the polymer particles including a polymerizable group that can be used in the fifth embodiment may be the same as the polymer particles including a heat reactive group of the third embodiment. The synthesizing method, average particle size, reacting temperature, etc. of the third embodiment may also apply to the fifth embodiment.

The amount of polymer particles including a polymerizable group contained in the image recording layer of the fifth embodiment is preferably 10 to 90% by mass, and more preferably 30 to 60% by mass based on the whole solid content of the image recording layer, in view of image forming properties and printing durability.

(Polymerization Initiator)

A polymerization initiator is necessarily added to the image recording layer according to the fifth embodiment. A reaction initiator is generated from the polymerization initiator due to energy of image exposure, and initiates and accelerates the reaction of the polymerizable compound. Examples of the polymerization initiator that can be used here include the polymerization initiators recited as the polymerization initiators of the first embodiment. The amount to be added is preferably in the same range as recited in the first embodiment.

(Light-to-Heat Converting Agent)

A light-to-heat converting agent that absorbs photo energy and converts it to heat may be added to the recording layer according to the fifth embodiment. As the light-to-heat converting agent used herein, the light-to-heat converting agents as exemplified for the recording layer of the first embodiment can be used. The amount to be added is preferably in the same range as recited in the first embodiment.

(Hydrophobic Resin)

A hydrophobic resin may be added to the image recording layer of the fifth embodiment in order to improve the film strength of the image portion. The hydrophobic resin that can be used herein include the same hydrophobic resin recited in the fourth embodiment of the image recording layer. The preferable range of the amount to be added is the same as recited in the fourth embodiment.

(Other Additives)

Hydrophilic resin, multifunctional monomers, higher aliphatic acids or derivatives thereof, inorganic particles, surfactants and plasticizers can be added, if necessary, to the recording layer according the fifth embodiment of the image recording layer. As the components used herein, the additives as exemplified for the recording layer of the first embodiment can be used, and the amount to be added is preferably in the same range as recited in the first embodiment.

[Formation of Image Recording Layer]

These image recording layers of the above-described first to fifth embodiments are each formed by dissolving the necessary components in a solvent to prepare a coating solution and applying the solution. The solvent used herein can include, but is not limited to, ethylenedichloride, cyclohexanone, methyl ethyl ketone, methanol, ethanol, propanol, ethyleneglycol monomethyl ether, 1-methoxy-2-propanol, 2-methoxyethyl acetate, 1-methoxy-2-propylacetate, dimethoxyethane, methyl lactate, ethyl lactate, N,N-dimethylacetamide, N,N-dimethylformamide, tetramethylurea, N-methylpyrrolidone, dimethylsulfoxide, sulforane, γ-butyrolactone and toluene, water. These solvent are used solely or as a mixture. The concentration of the solid portion of the coating solution is preferably 1 to 50% by mass.

Although the amount of the recording layer (solid portion) on the substrate after application and drying differs depending on the intended use, preferred amount is generally 0.5 to 5.0 g/m². When the amount of application is low, the apparent sensitivity is increased, but the film property of the recording layer that carries out a function of image recording is decreased.

The application can be carried out by various methods. For example, bar coater application, rotation application, spray application, curtain application, dip application, air knife application, blade application and roll application can be exemplified.

[Overcoat Layer]

For the planographic printing plate precursor of the invention, an overcoat layer including a water soluble resin disclosed in JP-A Nos. 2001-162961 or 2002-19318 can be provided on the recording layer so as to protect the surface of the recording layer from contamination by lipophilic substances during storage and from scratch and fingerprint contamination by contact of hands and fingers during handling.

Specific examples of the water soluble resin used for the overcoat layer can include, natural polymer compounds such as gum arabic, water soluble soy polysaccharide, cellulose derivative (for example, carboxymethyl cellulose, carboxyethyl cellulose and methyl cellulose), modified forms thereof, white dextrin, pullulane and enzyme decomposition etherified dextrin, synthetic polymer compounds such as polyvinylalcohol (hydrolysis rate of polyvinyl acetate is not less than 65%), polyacrylic acid and an alkaline metal salt and an amine salt thereof, polyacrylic acid copolymer and an alkaline metal salt and an amine salt thereof, polymethacrylic acid and an alkaline metal salt and an amine salt thereof, vinylalcohol/acrylic acid copolymer and an alkaline metal salt and an amine salt thereof, polyacrylamide and a copolymer thereof, polyhydroxyethylacrylate, polyvinylpyrrolidone and a copolymer thereof, polyvinylmethylether, vinylmethylether/maleic anhydride copolymer, poly(2-acrylamide-2-methyl-1-propanesulfonic acid) and an alkaline metal salt and an amine salt thereof, poly(2-acrylamide-2-methyl-1-propanesulfonic acid) copolymer and an alkaline metal salt and an amine salt thereof. According to the purpose, these resins can be used as a blend of two or more kinds. However, the invention is not limited to these examples.

A light-to-heat converting agent can be included in the overcoat layer so as to improve sensitivity. Preferable examples of the light-to-heat converting agent include a water soluble infrared radiation absorbing colorant. For example, (IR-1) to (IR-11) shown in the description of the recording layer are preferably used.

When an aqueous solution is applied, a nonionic surfactant can be added to the overcoat layer for the purpose of ensuring uniformness of application. Specific examples of the nonionic surfactant can include sorbitan tristearate, sorbitan monopalmitate, sorbitan trioleate, stearic acid monoglyceride, polyoxyethylene nonyl phenyl ether and polyoxyethylene dodecyl ether. The ratio of the nonionic surfactant in the whole solid in the overcoat layer is preferably 0.05 to 5% by mass, and more preferably 1 to 3% by mass.

Furthermore, a compound having fluorine atom or silicon atom disclosed in JP-A No. 2001-341448 can be added to the overcoat layer so as to prevent adhesion between the stacked plates during storage.

The thickness of the overcoat layer according to the invention is preferably 0.1 to 4.0 μm, and more preferably 0.1 to 1.0 μm. In this range, contamination of the recording layer by lipophilic substance can be prevented without deteriorating removing property of the overcoat layer on a printer.

[Substrate]

The substrate that can be used for the planographic printing plate precursor according the invention is a plate material having stable dimension, for example, paper, paper on which plastic (for example, polyethylene, polypropylene and polystyrene) has been laminated, metal plates (for example, aluminum, zinc and copper), plastic films (for example, cellulose diacetate, cellulose triacetate, cellulose propionate, cellulose butyrate, cellulose acetate butyrate, cellulose nitrate, polyethylene terephtalate, polyethylene, polystyrene, polypropylene, polycarbonate and polyvinylacetal), paper or plastic films on which the above-mentioned metal has been laminated or deposited. Preferable substrate includes aluminum plate.

The aluminum plate is an alloy plate including a pure aluminum plate and aluminum as main components and trace amount of heteroelement, and more specifically, a thin film of aluminum or aluminum alloy on which a plastic has been laminated. The heteroelement included in the aluminum alloy includes silicon, iron, manganese, copper, magnesium, chromium, zinc, bismuth, nickel and titanium. The amount to be included in the alloy of the heteroelement is at most not more than 10% by mass. The plate may be an aluminum plate obtained from an aluminum ingot obtained by DC metal casting method, or an aluminum plate obtained from an ingot by continuous metal casting method. However, aluminum plates of conventionally known and used materials can be suitably used for the aluminum plate applied to the invention.

The thickness of the substrate used in the invention is 0.05 mm to 0.6 mm, preferably 0.1 mm to 0.4 mm, and specifically preferably 0.15 mm to 0.3 mm.

Before using the aluminum plate, surface treatment such as surface roughening or anodizing is preferably carried out on the surface. By the surface treatment, hydrophilicity is improved and adhesiveness with the recording layer is easily ensured.

The surface roughening treatment of the surface of the aluminum plate can be carried out by various methods such as a method including mechanical surface roughening, a method including electrochemically dissolving the surface and surface roughening and a method including chemically selecting and dissolving the surface. As the mechanical method, known methods such as ball abrasion method, brush abrasion method, blast abrasion method and buffing method can be used. As the chemical method, a method including dipping in a saturated aqueous solution of aluminum salt of a mineral acid as disclosed in JP-A No. 54-31187 is suitable. As the electrochemical surface roughening method, a method carried out using alternate or direct current in an electrolyte solution including an acid such as chloric acid or nitric acid. Alternatively, electrolyte surface roughening method using a mixed acid as disclosed in JP-A No. 54-63902 can be used. The surface roughening by the above-mentioned method is preferably carried out in the range so that the center line average roughness (Ra) of the surface of the aluminum plate becomes 0.2 to 1.0 μm.

The aluminum plate subjected to the surface roughening is subjected to, if necessary, alkaline etching process using an aqueous solution such as potassium hydroxide or sodium hydroxide, and further subjected to neutralization. If desired, anodizing treatment is carried out so as to improve abrasion resistance.

As the electrolyte used for the anodizing treatment of aluminum plate, various electrolytes those form porous oxidized film can be used, and nitric acid, chloric acid, oxalic acid, chromium acid or a mixed acid thereof are generally used. The concentration of the electrolyte is suitably determined depending on the kind of electrolyte. Although the treatment condition for anodizing cannot be generally specified since it varies depending on the electrolyte used, the suitable condition is generally in the range wherein the concentration of the electrolyte is 1 to 80% by mass in solution, the liquid temperature is 5 to 70° C., electric current density is 5 to 60 A/dm²

, voltage is 1 to 100 V, and electrolyte period is 10 seconds to 5 min. The amount of the oxidized film to be formed is 1.0 to 5.0 g/m², specifically 1.5 to 4.0 g/m².

The substrate treated by the above-mentioned surface treatment and having an anodizing film can be used directly for the invention. Alternatively, if necessary, the substrate can be subjected to a treatment suitably selected from a treatment for enlarging micropores of the anodizing film, a treatment for closing micropores of the anodizing film, and a surface hydrophilize treatment including dipping the anodizing film in an aqueous solution including a hydrophilic compound, as disclosed in JP-A Nos. 2001-253181 and 2001-322365, so as to improving adhesiveness to the upper layer, hydrophilicity and antifouling property, adiathermancy and the like.

Preferable hydrophilic compounds for the hydrophilize treatment includes polyvinylphosphonic acid, a compound having sulfonic acid group, saccharide compound, citric acid, alkaline metal silicate, zirconium potassium fluoride and phosphate/inorganic fluorine compound.

When the substrate having insufficient surface hydrophilic such as a polyester film as a substrate that can be used for the invention, it is desirable to apply a hydrophilic layer to render the surface hydrophilic. Preferable hydrophilic layer includes a hydrophilic layer obtained by applying a coating solution including a colloid of oxide or hydroxide of at least one element selected from beryllium, magnesium, aluminum, silicone, titanium, boron, germanium, tin, zirconium, iron, vanadium, antimony and transition metals as disclosed in JP-A 2001-199175. Among these, a hydrophilic layer obtained by applying a coating solution of a colloid of an oxide or a hydroxide of silicone.

In the invention, prior to the application of the recording layer, if necessary, an inorganic undercoat layer of a water soluble metal salt such as zinc borate, or an organic undercoat layer including carboxymethyl cellulose, dextrin or polyacrylic acid, as disclosed in JP-A No. 2001-322365, can be applied. The undercoat layers can include the above-mentioned light-to-heat converting agent.

The planographic printing plate precursor to which the method of the invention can be applied can be obtained as above. The planographic printing plate precursor is a developing-on-press type planographic printing plate precursor, to which the image forming method of the invention can be applied, on which an image can be formed by infrared radiation irradiation, and which can be subjected to a printing process without going through a developing process.

### EXAMPLES

Hereinafter, the present invention will be explained in detail with referring to the Examples. However, these Examples should not be construed to limit the scope of the invention.

[Preparation of Substrate]

A liquid of JIS A1050 alloy including aluminum (not less than 99.5% by mass), Fe (0.30% by mass), Si (0.10% by mass), Ti (0.02% by mass) and Cu (0.013% by mass) was subjected to cleaning treatment and casted. During the cleaning treatment, the liquid was degassed so as to remove unnecessary gas such as hydrogen in the liquid, and was treated using a ceramic tube filter. Metal casting was carried out by DC casting method. The solidified ingot having a plate thickness of 500 mm was surface shaved by 10 mm from the surface, and subjected to homogenizing treatment at 550° C. for 10 hours so that the compound between metal is not enlarged.

The ingot was subjected to hot rolling at 400° C., annealed at 500° C. for 60 seconds in a continuous annealing furnace and subjected to cool rolling to give an aluminum rolled plate having a plate thickness of 0.30 mm. The center line average surface roughness Ra after the cool rolling was controlled to 0.2 μm by controlling the roughness of the rolling roll. The plate was then subjected to a tension leveler to improve planarity.

The surface treatment for making a planographic printing plate substrate was then carried out. Firstly, degreasing treatment was carried out at B 50° C. for 30 seconds using 10% by mass of sodium aluminate aqueous solution to remove a rolling oil on the surface of the aluminum plate, and neutralization was carried out at 50° C. for 30 seconds using 30% by mass of nitric acid aqueous solution, and the smuts was removed. Surface roughening of the surface of the substrate, i.e., sand-dressing, was then carried out so as to improve the adhesiveness between the substrate and the recording layer and to provide the non-image portion with water holding property. An aqueous solution including nitric acid (1% by mass) and aluminum nitrate (0.5% by mass) was kept at 45° C., and electrolysis sand-dressing was carried out by providing anode electric charge of 240 C/dm² using an indirect power dispatching cell and an alternate wave form having the electric current density 20 A/dm² and the duty ratio of 1:1, while an aluminum web is flowed in the aqueous solution. An etching process was then carried out using 10% by mass sodium aluminate aqueous solution at 50° C. for 30 seconds, and neutralization was carried out at 50° C. for 30 seconds using 30% by mass of nitric acid aqueous solution, and the smuts was removed. Furthermore, an anodized film was formed on the substrate by anodizing so as to improve abrasion resistance, chemical resistance and water holding property. Electrolysis was carried out using an aqueous solution of nitric acid (20% by mass) as an electrolyte at 35° C., and using an indirect power dispatching cell and a direct current of 14 A/dm², while the aluminum web was passed in the electrolyte, to give an anodized film of 2.5 g/m².

Silicate treatment was then carried out so as to assure the hydrophilicity for the non-image portion of the printing plate. The treatment was carried out by passing the aluminum web in 1.5% by mass aqueous solution of No. 3 sodium silicate, which was maintained at 70° C., so that the contacting period became 15 seconds, and washing the web by water. The amount of Si adhered was 10 mg/m². The center line surface roughness Ra of the thus-prepared substrate was 0.25 μm.

### Synthetic Example 1

### Polymer Particles Having Heat Reactive Functional Group

To a four-necked flask (1000 ml) were attached a stirrer, a thermometer, a dropping funnel, a nitrogen induction tube and a reflux condenser. Distilled water (350 ml) was added thereto and heated until the inner temperature reached to 80° C., while nitrogen gas was introduced thereto to remove oxygen. Sodium dodecyl nitrate (1.0 g) as a dispersing agent and a polyvinylalcohol (manufactured by Nippon Synthetic Chemical Industry Co., Ltd., KL05, 1.5 g) were added thereto, ammonium persulfate (0.45 g) as an initiator was added thereto, and glycidyl methacrylate (45 g) and styrene (45 g) were then dropwise-added thereto using a dropping funnel for about 1 hour. After the addition was completed, the reaction was continued for 5 hours, and the unreacted monomer was removed by water vapor distillation. The reaction solution was then cooled, and the pH was adjusted to pH 6 using aqueous ammonium. Lastly, pure water was added so that the non-volatile components became 15% by mass to give a water dispersion liquid of polymer particles having epoxy group as a heat reactive group. The particle size distribution of these polymer particles has a maximum value at the particles size of 80 nm.

The particle size distribution was calculated by taking a microscopic photograph of the polymer particles, measuring the particle size of 5000 particles in total on the photograph, and dividing the obtained values of the particle size from the maximum value to 0 into 50 parts using a logarithmic scale, and plotting the frequency of appearance of each particle size. For the non-spherical particles, the value of the spherical particles having the same particle area on the photograph was regarded as the particle size thereof.

### Synthetic Example 2

### Microcapsules Including a Cationic Polymerizable Compound

As an oil phase component, bis(vinyloxyethyl)ether of bisphenol A (4.5 g), an adduct of trimethylolpropane and xylylenediisocyanate (manufactured by Mitsui Takeda Chemical Co., Ltd., TAKENATE D-110N, microcapsule wall material, 5 g), MILLIONATE MR-200 (manufactured by Japan Polyurethane Co., Ltd., aromatic isocyanate oligomer for microcapsule wall material, 3.75 g), an infrared radiation absorbing colorant (IR-27 described in the present specification, 1.5 g), PIONINE A41C (Takemoto Oil and Fat Co., Ltd., surfactant, 0.1 g) were dissolved in ethyl acetate (18.4 g). As an aqueous component, 4 % by mass aqueous solution of PVA205 (manufactured by Kuraray Co., Ltd., polyvinylalcohol, 37.5 g) was prepared. The oil phase component and the aqueous phase component were emulsified using a homogenizer at 12000 rpm for 10 min. A solution of tetraethylenepentamine (pentafunctional amine, microcapsule wall crosslinking agent, 0.38 g) in water (26 g) was added thereto, and the mixture was stirred 30 min with water-cooling, and further stirred at 65° C. for 3 hours. The solid concentration of the thus-obtained microcapsule dispersion liquid was 24% by mass, and the average particle size was 0.3 μm.

### Synthetic Example 3

### Polymer Particles Having Radical Polymerizable Group

To a reaction vessel were added allyl methacrylate (7.5 g), styrene (7.5 g) and an aqueous solution of polyoxyethylene phenol (concentration 9.8×10⁻³ mol/l, 200 ml), and the mixture was stirred at 250 rpm while the reaction system was purged with nitrogen gas. The temperature of the reaction solution was raised to 25° C., and an aqueous solution of cerium (IV) ammonium salt (concentration 0.984×10⁻³ mol/l, 10 ml) was added thereto while ammonium nitrate (concentration 58.8×10⁻³ mol/l) was added thereto to adjust the pH to the range of 1.3 to 1.4. The reaction mixture was then stirred for 8 hours. The concentration of the solid content of the thus-obtained mixture was 9.5%, and the average particle size was 0.4 μm.

### Synthetic Example 4

### Polymer Microcapsules Comprising Radical Polymerizable Compound

As an oil phase component, an adduct of trimethylolpropane and xylylenediisocyanate (trade name: TAKENATE D-110N, manufactured by Mitsui Takeda Chemical Co., Ltd., microcapsule wall material, 10 g), pentaerythritol triacrylate (trade name: SR444, manufactured by Nippon Kayaku Co., Ltd., 5.6 g), photothermal converter IR-30 described in the present specification, 0.15 g), PIONIN A41C (manufactured by Takemoto Oil and Fat Co., Ltd., 0.12 g) were dissolved in ethyl acetate (17 g). As an aqueous phase component, 4% by mass aqueous solution of PVA205 (manufactured by Kuraray Co., Ltd., polyvinyl alcohol, 37.5 g) was prepared. The oil phase component and the aqueous phase component were emulsified using a homogenizer at 10000 rpm for 10 min. Water (25 g) was then added to the mixture and stirred for 30 min at ambient temperature and for 3 hr at 40° C. The concentration of the solid content of the thus-obtained microcapsule dispersion liquid was 20% by mass, and the average particle size was 0.25 μm.

(Preparation of Planographic Printing Plate Precursor A)

The recording layer coating solution 1 described below, which includes the polymer particles obtained in the Synthetic Example was applied on the aluminum substrate obtained above by bar coating, and dried in an oven under the condition of 70° C. and 120 seconds to give the planographic printing plate precursor A in which the dry amount of application of 0.8 g/m² of the recording layer.

<Recording layer coating solution 1>

| | |
|---|---|
| Polymer particles of the Synthetic Example | 10.0 g |
| Light-to-heat converting agent (IR-10 described in | 1.0 g |
| the present specification) | |
| Polyacrylic acid (weight average molecular weight | 1.0 g |
| 25,000) | |
| Water | 50.0 g |

(Preparation of Planographic Printing Plate Precursor B)

The recording layer coating solution 2 described below, which includes the polymer particles obtained in the Synthetic Example was applied on the aluminum substrate obtained above by bar coating, and dried in an oven under the condition of 100° C. and 60 seconds to give the planographic printing plate precursor B in which the dry amount of application of 1.0 g/m² of the recording layer.

<Recording layer coating solution 2>

| | |
|---|---|
| Water | 35.4 g |
| Microcapsule dispersion liquid of Synthetic | 90 g |
| Example | |
| Acid generator (AI-7 described in the present | 0.24 g |
| specification) | |

(Preparation of Planographic Printing Plate Precursor C)

The recording layer coating solution described below was applied on the aluminum substrate obtained above by bar coating, and dried in an oven under the condition of 80° C. and 90 seconds to give the planographic printing plate precursor C, in which the dry amount of application of the recording layer was 1.0 g/m².

<Recording layer coating solution 3>

| | |
|---|---|
| Dispersion of the above polymer particles | 15 g |
| Photothermal converter (IR-12 described in the | 0.1 g |
| present specification) | |
| Polyacrylic acid (weight average molecular weight | 0.05 g |
| 25,000) | |
| Ethoxylated trimethylolpropane triacrylate (trade | 0.05 g |
| name: SR9035, manufactured by Nippon Kayaku | |
| Co., Ltd.) | |
| Radical generator (AS-11 described in the present | 0.05 g |
| specification) | |
| Water | 10 g |

(Preparation of Planographic Printing Plate Precursor D)

The recording layer coating solution described below was applied on the aluminum substrate obtained above by bar coating, and dried in an oven under the condition of 80° C. and 90 seconds to give the planographic printing plate precursor D, in which the dry amount of application of the recording layer was 1.0 g/m².

<Recording layer coating solution 4>

| | |
|---|---|
| Water | 40 g |
| Propylene glycol monomethyl ether | 40 g |
| Dispersion of the above polymer microcapsules | 25 g |
| Isocyanuric acid EO modified triacrylate (trade | 0.2 g |
| name: Aronix M-315, manufactured by Toa Gosei | |
| Co., Ltd.) | |
| Radical generator (AS-11 described in the present | 0.5 g |
| specification) | |
| Photothermal converter (IR-12 described in the | 0.15 g |
| present specification) | |
| Fluorochemical surfactant (trade name: Megaface | 0.05 g |
| F-171, manufactured by Dainippon Ink and | |
| Chemicals, Inc.) | |

(Exposure, Printing and Evaluation)

### Example 1

Example 1 relates to the image forming method according to the first aspect of the invention.

The planographic printing plate precursor A obtained above was subjected to image exposure using the image exposure device 10 according to the first embodiment of the invention (FIG. 1) or the image exposure device 100 according to the second embodiment of the invention (FIG. 6) under the condition of the output of 17 W, the number of revolutions of the outer surface drum of 100 rpm and the resolution of 2400 dpi. After 15 seconds, the plate was subjected to heating (post-heating) to 80° C. using the post-heating apparatus 38 and attached to a cylinder of a printer (trade name: SOR-M, manufactured by Heidelberger Druckmaschinen AG) without subjecting to developing process. Using dampening water including 4 volume % aqueous solution of IF102 (manufactured by Fuji Photo Film Co., Ltd.) and VALUES india ink (manufactured by Dainippon Ink and Chemicals, Inc.), the dampening water was supplied firstly and ink was then supplied. Paper was then supplied to carry out printing.

Exposure and printing using the planographic printing plate precursor B were then carried out according to the same processes for the planographic printing plate precursor A except that the post-heating temperature was changed to 170° C. in the exposure of the planographic printing plate precursor A.

During this method, the recording layer on the non-image portion was removed at the initial step of the printing process, which resulted in high quality of printing wherein the non-image portion had not been contaminated. The printing was then continued, and the printing durability was evaluated by measuring visually how many sheets could be printed with retaining sufficient ink concentration. The more the number of sheets is, the printing durability is evaluated to be more superior.

As a result, the number for the planographic printing plate precursor A was 50,000 sheets, the number for the planographic printing plate precursor B was 40,000 sheets, the number for the planographic printing plate precursor C was 50,000 sheets, and the number for the planographic printing plate precursor D was 60,000 sheets. By this method, it was confirmed that both planographic printing plate precursors had superior printing durability sufficient for practical use.

### Example 2

Example 2 relates to the image forming method according to the second aspect of the invention. The planographic printing plate precursor A obtained as above was attached to the image exposure device 210 of the embodiment of the invention, which was already explained based on FIGS. 7 and 8, and image exposure was carried out under the conditions of output of 17 W, the number of revolutions of the outer surface drum of 100 rpm and the resolution of 2400 dpi without carrying out a developing process. During the procedure, scanning exposure was carried out using IR laser L, and 15 seconds after the exposure was completed, the recording layer of the heating area including the image exposure area of the planographic printing plate precursor was spot-heated to 80° C. By this process, in the case wherein the planographic printing plate precursor A including the image recording layer of the first embodiment, the microcapsules became permeable effectively even in the vicinity of the interface of the recording layer and the substrate, and the generation reaction of an acid or a radical also proceeded effectively, which could result in an image being strong and superior in printing durability in accordance with high movability of the polymerizable compound and active species.

Exposure using the planographic printing plate precursor B was then carried out according to the same processes for the planographic printing plate precursor A except that the post-heating temperature was changed to 170° C. in the exposure of the planographic printing plate precursor A. In the case of use of the planographic printing plate precursor B including the image recording layer of the second embodiment, sufficient thermal energy could be supplied to the substrate even in the vicinity of the interface of the substrate, which could result in an image being strong and superior in printing durability by the proceeding of adhesion of particles by fusion and crosslinking reaction.

The planographic printing plate precursors A to D each was attached to a cylinder of a printer (trade name: SOR-M, manufactured by Heidelberger Druckmaschinen AG) without carrying out a developing process. Using dampening water including 4 volume % aqueous solution of IF102 (manufactured by Fuji Photo Film Co., Ltd.) and VALUES india ink (manufactured by Dainippon Ink and Chemicals, Inc.), dampening water was supplied firstly, ink was then supplied. Paper was then supplied to carry out printing.

During this process, the printing durability was evaluated by measuring visually how many sheets could be printed with retaining sufficient ink concentration. The more the number of sheets is, the printing durability is evaluated to be more superior.

As a result, the number for the planographic printing plate precursor A was 50,000 sheets, the number for the planographic printing plate precursor B was 40,000 sheets, the number for the planographic printing plate precursor C was 50,000 sheets, and the number for the planographic printing plate precursor D was 60,000 sheets. By this method, it was confirmed that both planographic printing plate precursors had superior printing durability sufficient for practical use.

### Example 3

Example 3 relates to the image forming method according to the third aspect of the invention.

The planographic printing plate precursor A obtained as above was attached to the image exposure device 310 of the embodiment of the invention, which was already explained based on FIGS. 9 and 10, and image exposure was carried out under the conditions of output of 17 W, the number of revolutions of the outer surface drum of 100 rpm and the resolution of 2400 dpi. Simultaneously with the image exposure, the recording layer of the heating area A_{HT} including the exposure area A_{IR} in the planographic printing plate precursor was heated to 80° C. By this heating, the microcapsules could fuse effectively even in the vicinity of the interface of the recording layer and the substrate, which could result in an image being strong and superior in printing durability.

Exposure using the planographic printing plate precursor B was carried out in the same manner as in the exposure of the planographic printing plate precursor A, except that the heating temperature of the heating area A_{HT} including the exposure area A_{IR} was changed to 170° C. By this heating, the microcapsules became permeable effectively, and the acid generation reaction also proceeded effectively, which could result in an image being strong and superior in printing durability in accordance with having high movability of the polymerizable compound and active species.

Exposure using the planographic printing plate precursor C was carried out in the same manner as in the exposure of the planographic printing plate precursor A, except that the heating temperature of the heating area A_{HT} including the exposure area A_{IR} was changed to 90° C. By this heating, the crosslinking (polymerizing) reaction of polymer particles including a polymerizable group proceeded effectively even in the vicinity of the interface of the recording layer and the substrate, which could result in an image being strong and superior in printing durability.

Exposure using the planographic printing plate precursor D was carried out in the same manner as in the exposure of the planographic printing plate precursor A, except that the heating temperature of the heating area A_{HT} including the exposure area A_{IR} was changed to 120° C. By this heating, the microcapsules became permeable effectively, and the radical generation reaction also proceeded effectively, which could result in an image being strong and superior in printing durability in accordance with having high movability of the polymerizable compound and active species.

After the image exposure for each of the planographic printing plate precursors A to D was completed, the plates A to D each was attached to a cylinder of a printer (trade name: SOR-M, manufactured by Heidelberger Druckmaschinen AG) without carrying out a developing process. Using dampening water including 4 volume % aqueous solution of IF102 (manufactured by Fuji Photo Film Co., Ltd.) and VALUES india ink (manufactured by Dainippon Ink and Chemicals, Inc.), dampening water was supplied firstly, and ink was then supplied. Paper was then supplied to carry out printing.

During this process, the printing durability was evaluated by visually measuring how many sheets can be printed with retaining sufficient ink concentration. The more the number of sheets is, the printing durability is evaluated to be more superior.

As a result, the number for the planographic printing plate precursor A was 50,000 sheets, the number for the planographic printing plate precursor B was 40,000 sheets, the number for the planographic printing plate precursor C was 50,000 sheets, and the number for the planographic printing plate precursor D was 60,000 sheets. By this method, it was confirmed that both planographic printing plate precursors had superior printing durability sufficient for practical use.

According to the invention, an image forming method on a planographic printing plate precursor, which is capable of scanning exposure of an image based on a digital signal, capable of developing-on-press and being superior in printing durability, and an image-forming device used therefore can be provided.

1. A method for forming an image on a planographic printing plate precursor comprising a substrate and an image recording layer disposed thereon, the image recording layer comprising a hydrophobic precursor and a light-to-heat converting agent,
wherein the method comprises:
exposing the planographic printing plate precursor to infrared radiation to form an image on the image recording layer of the planographic printing plate precursor; and
post-heating the planographic printing plate precursor to a predetermined heating temperature.

2. The method of claim 1, wherein the hydrophobic precursor comprises at least one selected from the group consisting of (a) microcapsules comprising a compound having a heat reactive group, (b) thermoplastic polymer particles, and (c) polymer particles including a heat reactive group.

3. A method for forming an image on a planographic printing plate precursor comprising a substrate and an image recording layer disposed thereon, the image recording layer comprising a polymerizable compound, a polymerization initiator and a light-to-heat converting agent,
wherein the method comprises:
exposing the planographic printing plate precursor to infrared radiation to form an image on the image recording layer of the planographic printing plate precursor; and
post-heating the planographic printing plate precursor to a predetermined heating temperature.

4. The method of claim 3, wherein the polymerizable compound is contained in microcapsules.

5. The method of claim 3, wherein the polymerizable compound is polymer particles comprising a polymerizable group.

6. The method of claim 1, wherein the temperature for post-heating is from 35° C. to 230° C.

7. An image exposure device used for the method of claim 1, the device comprising:
a retention member to which the planographic printing plate precursor can be attached, the member retaining the attached planographic printing plate precursor,
means for exposing the planographic printing plate precursor retained by the retention member to infrared radiation to form an image on the image recording layer of the planographic printing plate precursor, and
means for post-heating the planographic printing plate precursor which has been detached from the retention member after the image formation to the heating temperature by thermal energy or electromagnetic energy supplied from a heat supplying portion extending linearly or planerly.

8. The image exposure device of claim 7, further comprising:
a receiving portion that receives the planographic printing plate precursor which has been detached from the retention member after the image formation; and
means for conveying the planographic printing plate precursor which has been detached from the retention member after the image formation, from the retention member to the receiving portion along a predetermined conveyer pathway,
wherein the means for post-heating is provided on the conveyer pathway.

9. An image exposure device used for the method of claim 3, the device comprising:
a retention member to which the planographic printing plate precursor can be attached, the member retaining the attached planographic printing plate precursor,
means for exposing the planographic printing plate precursor retained by the retention member to infrared radiation to form an image on the image recording layer of the planographic printing plate precursor, and
means for post-heating the planographic printing plate precursor which has been detached from the retention member after the image formation to the heating temperature by thermal energy or electromagnetic energy supplied from a heat supplying portion extending linearly or planerly.

10. The image exposure device of claim 9, further comprising:
a receiving portion that receives the planographic printing plate precursor which has been detached from the retention member after the image formation; and
means for conveying the planographic printing plate precursor which has been detached from the retention member after the image formation, from the retention member to the receiving portion along a predetermined conveyer pathway,
wherein the means for post-heating is provided on the conveyer pathway.

11. A method for forming an image on a planographic printing plate precursor comprising a substrate and an image recording layer disposed thereon, the image recording layer comprising a hydrophobic precursor and a light-to-heat converting agent,
wherein the method comprises:
applying scanning exposure to the planographic printing plate precursor with infrared radiation to form an image on the image recording layer of the planographic printing plate precursor; and
locally post-heating a heating area comprising an arbitrary area exposed to the infrared radiation on the image recording layer of the planographic printing plate precursor during the exposure of the planographic printing plate precursor, to a predetermined heating temperature, after the irradiation of the exposure area in the heating area with infrared radiation.

12. The method of claim 11, wherein the hydrophobic precursor comprises at least one selected from the group consisting of (a) microcapsules comprising a compound having a heat reactive group, (b) thermoplastic polymer particles, and (c) polymer particles comprising a heat reactive group.

13. A method for forming an image on a planographic printing plate precursor comprising a substrate and an image recording layer disposed thereon, the image recording layer comprising a polymerizable compound, a polymerization initiator and a light-to-heat converting agent,
wherein the method comprises:
applying scanning exposure to the planographic printing plate precursor with infrared radiation to form an image on the image recording layer of the planographic printing plate precursor; and
locally post-heating a heating area comprising an arbitrary area exposed to the infrared radiation on the image recording layer of the planographic printing plate precursor during the exposure of the planographic printing plate precursor, to a predetermined heating temperature, after the irradiation of the exposure area in the heating area with infrared radiation.

14. The method of claim 13, wherein the polymerizable compound is contained in microcapsules.

15. The method of claim 13, wherein the polymerizable compound is polymer particles comprising a polymerizable group.

16. The method of claim 11, wherein the temperature for post-heating is from 35° C. to 230° C.

17. The method of claim 11, wherein the heating of the heating area to the heating temperature by the post-heating is carried out within 1 min after completion of the exposure of the exposure area in the heating area.

18. An image exposure device used for the method of claim 11, the device comprising:
a retention member to which the planographic printing plate precursor can be attached, the member retaining the attached planographic printing plate precursor;
exposing means for scanning exposing the planographic printing plate precursor retained by the retention member with infrared radiation to form an image on the image recording layer of the planographic printing plate precursor; and
means for locally post-heating the heating area comprising the arbitrary exposure area on the planographic printing plate precursor to which the infrared radiation has been irradiated by the exposing means during the exposure of the planographic printing plate precursor to infrared radiation, to the predetermined heating temperature, after the irradiation to the exposure area in the heating area with infrared radiation.

19. The image exposure device of claim 18, wherein:
the exposing means comprises an exposure head that forms a beam spot of infrared radiation on the planographic printing plate precursor attached to the retention member, a carrier member on which the exposure head is mounted, and a feeding mechanism that moves the exposure head and the carrier member in the sub-scanning direction during the exposure of the planographic printing plate precursor; and
the means for post-heating comprises a heat supplying portion mounted on the carrier member so as to be positioned at any portion of the carrier member at an upstream side of the exposure head along the sub-scanning direction, the heat supplying portion heating the heating area to the heating temperature by supplying thermal energy or electromagnetic energy to the heating area while the heat supplying portion moves in the sub-scanning direction with the exposure head, during the exposure of the planographic printing plate precursor.

20. An image exposure device used for the method of claim 13, the device comprising:
a retention member to which the planographic printing plate precursor can be attached, the member retaining the attached planographic printing plate precursor;
exposing means for scanning exposing the planographic printing plate precursor retained by the retention member with infrared radiation to form an image on the image recording layer of the planographic printing plate precursor; and
means for locally post-heating the heating area comprising the arbitrary exposure area on the planographic printing plate precursor to which the infrared radiation has been irradiated by the exposing means during the exposure of the planographic printing plate precursor to infrared radiation, to the predetermined heating temperature, after the irradiation of the exposure area in the heating area with infrared radiation.

21. The image exposure device of claim 20, wherein:
the exposing means comprises an exposure head that forms a beam spot of infrared radiation on the planographic printing plate precursor attached to the retention member, a carrier member on which the exposure head is mounted, and a feeding mechanism that moves the exposure head and the carrier member in the sub-scanning direction during the exposure of the planographic printing plate precursor; and
the means for post-heating comprises a heat supplying portion mounted on the carrier member so as to be positioned at any portion of the carrier member at an upstream side of the exposure head along the sub-scanning direction, the heat supplying portion heating the heating area to the heating temperature by supplying thermal energy or electromagnetic energy to the heating area while the heat supplying portion moves in the sub-scanning direction with the exposure head, during the exposure of the planographic printing plate precursor.

22. A method for forming an image on a planographic printing plate precursor comprising a substrate and an image recording layer disposed thereon, the image recording layer comprising a hydrophobic precursor and a light-to-heat converting agent,
wherein the method comprises:
applying scanning exposure to the planographic printing plate precursor with infrared radiation to form an image on the image recording layer of the planographic printing plate precursor; and
locally heating a heating area comprising an arbitrary exposure area to which the infrared radiation is irradiated in the image recording layer of the planographic printing plate precursor during the exposure of the planographic printing plate precursor, to a predetermined heating temperature, during the exposure of the exposure area in the heating area.

23. The method of claim 22, wherein the hydrophobic precursor comprises at least one selected from the group consisting of (a) microcapsules comprising a compound having a heat reactive group, (b) thermoplastic polymer particles, and (c) polymer particles comprising a heat reactive group.

24. A method for forming an image on a planographic printing plate precursor comprising a substrate and an image recording layer disposed thereon, the image recording layer comprising a polymerizable compound, a polymerization initiator and a light-to-heat converting agent,
wherein the method comprises:
applying scanning exposure to the planographic printing plate precursor with infrared radiation to form an image on the image recording layer of the planographic printing plate precursor; and
locally heating a heating area comprising an arbitrary exposure area to which the infrared radiation is irradiated in the image recording layer of the planographic printing plate precursor during the exposure of the planographic printing plate precursor, to a predetermined heating temperature, during the exposure of the exposure area in the heating area.

25. The method of claim 24, wherein the polymerizable compound is contained in microcapsules.

26. The method of claim 24, wherein the polymerizable compound is polymer particles comprising a polymerizable group.

27. The method of claim 22, wherein the temperature for heating is from 35° C. to 230° C.

28. An image exposure device used for the method of claim 22, which comprises:
a retention member to which the planographic printing plate precursor can be attached, the member retaining the attached planographic printing plate precursor;
exposing means for scanning exposing the planographic printing plate precursor retained by the retention member with infrared radiation to form an image on the image recording layer of the planographic printing plate precursor; and
means for locally heating the heating area comprising the arbitrary exposure area to which the infrared radiation is irradiated on the image recording layer of the planographic printing plate precursor during the exposure of the planographic printing plate precursor, to the predetermined heating temperature, during the irradiation of the exposure area in the heating area.

29. The image exposure device of claim 28, wherein:
the exposing means comprises an exposure head for forming a beam spot of infrared radiation on the planographic printing plate precursor attached to the retention member, a carrier member on which the exposure head is mounted, and a feeding mechanism for moving the exposure head and the carrier member in the sub-scanning direction during the exposure of the planographic printing plate precursor; and
the means for heating comprises a heat supplying portion mounted on the carrier member, the heat supplying portion heating the heating area comprising the exposure area to which the beam spot formed by the exposure head is irradiated, to the heating temperature, by providing thermal energy or electromagnetic energy to the heating area while the heat supplying portion moves in the sub-scanning direction with the exposure head during the exposure of the planographic printing plate precursor to infrared radiation.

30. An image exposure device used for the method according to claim 24, which comprises:
a retention member to which the planographic printing plate precursor can be attached, the member retaining the attached planographic printing plate precursor;
exposing means for scanning exposing the planographic printing plate precursor retained by the retention member with infrared radiation to form an image on the image recording layer of the planographic printing plate precursor; and
means for locally heating the heating area comprising the arbitrary exposure area to which the infrared radiation is irradiated on the image recording layer of the planographic printing plate precursor during the exposure of the planographic printing plate precursor, to the predetermined heating temperature, during the irradiation of the exposure area in the heating area.

31. The image exposure device of claim 30, wherein:
the exposing means comprises an exposure head for forming a beam spot of infrared radiation on the planographic printing plate precursor attached to the retention member, a carrier member on which the exposure head is mounted, and a feeding mechanism for moving the exposure head and the carrier member in the sub-scanning direction during the exposure of the planographic printing plate precursor; and
the means for heating comprises a heat supplying portion mounted on the carrier member, the heat supplying portion heating the heating area comprising the exposure area to which the beam spot formed by the exposure head is irradiated, to the heating temperature, by providing thermal energy or electromagnetic energy to the heating area while the heat supplying portion moves in the sub-scanning direction with the exposure head during the exposure of the planographic printing plate precursor to infrared radiation.
